(19) United States
(12) Patent Application Publication
(10) Pub. No.: US 2026/0266670 A1
(43) Pub. Date: Sep. 10, 2026

(54) ULTRAHIGH-RESOLUTION MICRO-THERMOMETER USING SEMICONDUCTOR TUNNELING JUNCTIONS

(71) Applicant: RUTGERS, THE STATE UNIVERSITY OF NEW JERSEY, New Brunswick, NJ (US)

(72) Inventor: Amin REIHANI, Piscataway, NJ (US)

(21) Appl. No.: 19/472,127

(22) PCT Filed: Apr. 5, 2024
(86) PCT No.: PCT/US24/23398

§ 371 Date: Oct. 3, 2025

Related U.S. Application Data
(60) Provisional application No. 63/494,775, filed on Apr. 7, 2023.

(51) Int. Cl. G01K 15/00; G01K 7/01; G01K 7/24

(52) U.S. Cl. CPC G01K 15/005; G01K 7/01; G01K 7/24

(57) ABSTRACT

Techniques for ultra-high-resolution measurements of temperature include a semiconductor tunneling diode configured to be placed in thermal contact with a sample. An electrical resistor is electrically connected in series with the semiconductor tunneling diode. The electrical resistor defines a discontinuous edge between a tunneling current and a diffusion current of the semiconductor tunneling diode, with the discontinuous edge having a peak current and a valley current. A voltage source is electrically connected in series with the electrical resistor and is configured to produce a constant voltage V_{DC} summed with a temporally oscillating voltage V_{AC}. The time oscillating voltage V_{AC} causing an operating point of the semiconductor tunneling diode to oscillate between the peak current and the valley current. A processor is configured to determine temperature at the semiconductor tunneling diode based on an output current signal from the semiconductor tunneling diode. A low-pass filter is optionally included.

### CROSS-REFERENCE TO RELATED APPLICATIONS

This application is a National Stage entry of PCT/US24/23398 filed Apr. 5, 2024, which claims the benefit of U.S. Provisional Patent Application Ser. No. 63/494,775 filed Apr. 7, 2023, all of which is fully incorporated by reference.

### BACKGROUND

High-resolution thermometry is critical for probing chemical reactions, dissipation in electronic and quantum systems, nanoscale energy transport, infrared/millimeter-wave/terahertz detection for sensing, imaging and communication, and metabolism in biological systems. Integrating high-resolution thermometers directly into microscale devices and operating them at room temperature (about 20 degrees Celsius or centigrade, ° C., which is about 294 Kelvin, K) is essential for studies and applications where the time-resolved measurement of localized temperature changes is necessary, for example in bio-calorimeters, surface reaction measurements on nanomaterials, or bolometer arrays for infrared/millimeter wave/terahertz (THz) imaging applications. Towards this goal, researchers have developed various methods.

### SUMMARY

Achieving nanokelvin-resolution thermometry (i.e., being able to resolve a very small temperature change of <1 microKelvin, μK, 1 μK=10⁻⁶K) from microscale devices at room temperature remains an outstanding challenge. Recently, we have developed a photonic thermometer with optical readout—called the Band-Edge Thermometer (BET)—that achieves this goal by relying on the temperature-dependent bandgap of a semiconductor material.

Techniques are provided here for a new sensor to improve upon BET by using an electronic readout instead of optical readout. The proposed sensor is significantly less complex, more cost effective, and allows further improvements in miniaturization and response time. As used herein, temperature measurements with resolution finer than about 100 μK is called ultra-high resolution thermometry and includes nanokelvin resolution in some embodiments. Because a diode generally allows current in a primary direction from anode to cathode of the diode, electric circuit components are herein said to be positioned “up current” or “down current” of the primary current direction relative to each other.

In a first set of embodiments, an apparatus for ultra-high-resolution measurements of temperature includes a semiconductor tunneling diode configured to be placed in thermal contact with a sample. The apparatus also includes an electrical resistor electrically connected in series with and up current of the semiconductor tunneling diode. The electrical resistor defines a discontinuous edge between a tunneling current and a diffusion current of the semiconductor tunneling diode, with the discontinuous edge having a peak current and a valley current. The apparatus further includes a voltage source electrically connected in series with and up current of the electrical resistor and configured to produce a constant voltage V_{DC} summed with a temporally oscillating voltage V_{AC}. The time oscillating voltage V_{AC} causes an operating point of the semiconductor tunneling diode to oscillate between the peak current and the valley current. The apparatus even still further includes a processor configured to determine temperature at the semiconductor tunneling diode based at least in part on a current signal output from the semiconductor tunneling diode.

In some embodiments of the first set, the apparatus further includes a low pass filter connected in series with and down current of the semiconductor tunneling diode and in series and up current of the processor. In some embodiments the apparatus includes a lock-in amplifier to extract the amplitude of current oscillation at excitation voltage (V_{AC}) frequency or harmonics of excitation voltage frequency.

In some embodiments of the first set, the processor is further configured to determine temperature at the semiconductor tunneling diode based on the current signal output from the semiconductor tunneling diode and a calibration function that relates the current signal output to temperature based on calibration data for samples with known temperature.

In some embodiments of the first set, the apparatus also includes a transimpedance amplifier configured to convert a current signal output from the semiconductor tunneling diode to a voltage signal.

In some embodiments of the first set, the apparatus also includes an analog to digital converter configured to convert an analog signal down current from the semiconductor tunneling diode to a digital data sequence input to the processor.

In some embodiments of the first set, the voltage source includes a precision voltage reference configured to output a constant voltage. The voltage source also includes a waveform generator configured to output a temporally oscillating voltage. The voltage source further includes a summing amplifier configured to combine with variable gains the constant voltage and the temporally oscillating voltage to produce the constant voltage V_{DC} summed with the time oscillating voltage V_{AC}.

In some embodiments of the first set, the processor is configured to determine temperature at the semiconductor tunneling diode based on a duty cycle width of the current signal output from the semiconductor tunneling diode or of a voltage signal based on the current signal.

In some embodiments of the first set, the processor is configured to determine temperature at the semiconductor tunneling diode based on a time average of the current signal output from the semiconductor tunneling diode or of a voltage signal based on the current signal.

In some embodiments of the first set, the processor is further configured to determine heat flow in a sample in thermal contact with the semiconductor tunneling diode.

In some embodiments of the first set, the apparatus also includes a thermal conductor configured to provide thermal contact between the semiconductor tunneling diode and a sample.

In a second set of embodiments, a bolometer for broadband detection of electromagnetic radiation includes a semiconductor tunneling diode configured to be exposed to electromagnetic radiation. The bolometer includes an electrical resistor electrically connected in series with and up current of the semiconductor tunneling diode. The electrical resistor defines a discontinuous edge between a tunneling current and a diffusion current of the semiconductor tunneling diode, with the discontinuous edge having a peak current and a valley current. The bolometer further includes a voltage source electrically connected in series with and up current of the electrical resistor and configured to produce a constant voltage V_{DC} summed with a temporally oscillating voltage V_{AC}. The time oscillating voltage V_{AC} causes an operating point of the semiconductor tunneling diode to oscillate between the peak current and the valley current. The bolometer even still further includes a processor configured to determine temperature at the semiconductor tunneling diode based at least in part on a current signal including the time-averaged current or current oscillation amplitude at first or higher harmonics of V_{AC} frequency output from the semiconductor tunneling diode.

In some embodiments, the semiconductor tunneling diode is configured as a heavily-doped semiconductor tunneling diode having a free carrier density of at least 10¹⁸ cm⁻³ and greater, with the heavily-doped semiconductor tunneling diode enhancing detection of the electromagnetic radiation.

In some embodiments, the heavily-doped semiconductor tunneling diode absorbs photons in the electromagnetic radiation and emits phonons in response to the absorbed photons, with the phonons assisting in tunneling of particles through a positive-to-negative (P-N) junction of the heavily-doped semiconductor tunneling diode.

In some embodiments, the bolometer further comprises an absorber layer on an upper surface of the semiconductor tunneling diode and exposed to the electromagnetic radiation, with the absorber layer configured to enhance detection of the electromagnetic radiation.

In some embodiments, the absorber layer absorbs photons in the electromagnetic radiation and emits phonons in response to the absorbed photons, with the phonons assisting in tunneling of particles through a positive-to-negative (P-N) junction of the semiconductor tunneling diode.

In a third set of embodiments, a microfluidic calorimeter is configured to determine heat from a sample within a microfluidic channel that contains a fluid or gas in contact with the sample. The sample may be, for example, biological, a single cell, a solution, a nanomaterial or a powder.

In one of the embodiments, the microfluidic calorimeter is configured as an isothermal microfluidic calorimeter that includes a single microfluidic channel in thermal contact with at least one temperature-controlled thermal shield. A first semiconductor tunneling diode is coupled to the microfluidic channel and adjacent the sample. A first electrical resistor electrically is connected in series with and up current of the first semiconductor tunneling diode to define a discontinuous edge between a tunneling current and a diffusion current of the first semiconductor tunneling diode, with the discontinuous edge having a peak current and a valley current.

A second semiconductor tunneling diode is coupled to the microfluidic channel and spaced away from the sample. A second electrical resistor is electrically connected in series with and up current of the second semiconductor tunneling diode to define a discontinuous edge between a tunneling current and a diffusion current of the second semiconductor tunneling diode, with the discontinuous edge having a peak current and a valley current.

A voltage source is electrically connected in series with and up current of the first and second electrical resistors and is configured to produce a constant voltage V_{DC} summed with a time oscillating voltage V_{AC}, with the time oscillating voltage V_{AC} causing an operating point of the first and second semiconductor tunneling diodes to respectively oscillate between the peak current and the valley current. A processor is configured to determine respective temperatures at the first and second semiconductor tunneling diodes based at least in part on a respective current signal output from the first and second semiconductor tunneling diodes, with the respective temperatures being used by the processor to determine a heat flow released by the sample.

In another one of the embodiments, the microfluidic calorimeter is configured as differential isothermal or scanning microfluidic calorimeter system by including a reference microfluidic channel in thermal contact with the at least one temperature-controlled thermal shield, and comprising a fluid or gas within the reference microfluidic channel.

The microfluidic calorimeter further comprises a third semiconductor tunneling diode coupled to the reference microfluidic channel, and a third electrical resistor electrically connected in series with and up current of the third semiconductor tunneling diode to define a discontinuous edge between a tunneling current and a diffusion current of the third semiconductor tunneling diode, with the discontinuous edge having a peak current and a valley current.

A fourth semiconductor tunneling diode is coupled to the microfluidic channel and spaced away from the third semiconductor tunneling diode, and a fourth electrical resistor electrically is connected in series with and up current of the fourth semiconductor tunneling diode to define a discontinuous edge between a tunneling current and a diffusion current of the fourth semiconductor tunneling diode, with the discontinuous edge having a peak current and a valley current.

The voltage source is now electrically connected in series with and up current of the third and fourth electrical resistors and configured to produce a constant voltage V_{DC} summed with a time oscillating voltage V_{AC}, with the time oscillating voltage V_{AC} causing an operating point of the third and fourth semiconductor tunneling diodes to respectively oscillate between the peak current and the valley current. The processor is further configured to determine respective temperatures at the third and fourth semiconductor tunneling diodes based at least in part on a respective current signal output from the third and fourth semiconductor tunneling diodes, with the respective temperatures being used by the processor to determine a heat flow released by the sample.

In other sets of embodiments a system, method, processor or computer readable medium is configured to use the apparatus of the first set of embodiments.

Still other aspects, features, and advantages are readily apparent from the following detailed description, simply by illustrating a number of particular embodiments and implementations, including the best mode contemplated for carrying out the invention. Other embodiments are also capable of other and different features and advantages, and its several details can be modified in various obvious respects, all without departing from the spirit and scope of the invention. Accordingly, the drawings and description are to be regarded as illustrative in nature, and not as restrictive.

### BRIEF DESCRIPTION OF THE DRAWINGS

Embodiments are illustrated by way of example, and not by way of limitation, in the figures of the accompanying drawings in which like reference numerals refer to similar elements and in which:

FIG. 1A is a schematic plot that illustrates example static current-voltage characteristic of a typical tunnel diode, used in various embodiments;

FIG. 1B through FIG. 1F show the simplified energy-band diagrams of a tunnel diode at absolute zero temperature and at various bias conditions, as used in various embodiments;

FIG. 2A is a block diagram that illustrates an example calorimeter system, according to an embodiment;

FIG. 2B is a block diagram that illustrates an example apparatus for measuring temperature electronically using a semiconductor tunneling diode, according to an embodiment;

FIG. 3A through FIG. 3C are graphs that illustrate example outputs from a semiconductor tunneling diode, as used in various embodiments;

FIG. 4 is a graph that illustrates example output currents from a semiconductor tunneling diode at different temperatures when driven by a sum of a constant bias voltage and a temporally oscillating voltage, according to an embodiment;

FIG. 5 and FIG. 6 are graphs that illustrates example calibration functions, according to an embodiment;

FIG. 7 is a block diagram that illustrates an example bolometer system, according to an embodiment;

FIG. 8A is an energy diagram during a two-phonon indirect interband tunneling process in a tunnel diode, according to an embodiment;

FIG. 8B is a phonon-assisted tunneling spectrum of a silicon tunnel diode, according to an embodiment;

FIG. 9A is a side view of a heavily-doped semiconductor tunneling diode absorbing photons and causing an optical phonon emission, according to an embodiment.

FIG. 9B is a side view of a semiconductor tunneling diode with an absorber layer absorbing photons and causing an optical phonon emission, according to an embodiment.

FIG. 10A is a block diagram that illustrates an example isothermal microfluidic calorimeter system, according to an embodiment;

FIG. 10B is a block diagram that illustrates an example differential isothermal or scanning microfluidic calorimeter system, according to an embodiment;

FIG. 11 is a flowchart that illustrates an example method for making and using the system of FIG. 5, according to an embodiment; and

FIG. 12 is a block diagram that illustrates a computer system upon which an embodiment of the invention may be implemented.

### DETAILED DESCRIPTION

A method and apparatus are described for ultra-high-resolution thermometry. In the following description, for the purposes of explanation, numerous specific details are set forth in order to provide a thorough understanding of the present invention. It will be apparent, however, to one skilled in the art that the present invention may be practiced without these specific details. In other instances, well-known structures and devices are shown in block diagram form in order to avoid unnecessarily obscuring the present invention.

Some embodiments of the invention are described below in the context of a calorimeter operating at or near room temperature. However, the invention is not limited to this context. In other embodiments the ultra-high-resolution temperature measurements can be made for any uses of temperature, including calorimeters, at or apart from room temperature by changing one or more characteristics of the calibration data and one or more circuit components, such as the semiconductor tunneling diode, the voltage source and resistors connected in series with the diode.

### 1. OVERVIEW

A new ultra-high resolution temperature measurement sensor—called a Tunneling-Diffusion Edge Sensor (TDES)—consists of a semiconductor tunneling diode structure, configured so an electrical current is passed as a result of quantum tunneling of charge across the barrier when a bias voltage is applied across the device. The current-voltage characteristic of such tunneling diodes is temperature dependent as a result of temperature-dependent band structure and carrier population in the semiconductor materials. Therefore, the electrical resistance of the tunnel diode at a sharp negative differential resistance region, when a transition between tunneling and diffusion current occurs, provides a very sensitive signal for temperature measurement. This allows ultra-high- and nanokelvin-resolution thermometry with a microscale footprint diode at room temperature when operated as part of a stand-alone thermometer or as part of calorimeter.

Tunneling is a quantum mechanical phenomenon that allows particles to cross a potential barrier although the energy of the particle is less than the potential barrier. The probability of tunneling is significantly dependent on the width of the potential barrier and the energy of the particles. In this context, we are interested in tunneling of charge carriers, which occurs if the barrier is thin enough and empty sites are available in the right range of energies so that carriers from one side of the barrier can tunnel to these empty sites.

A tunnel diode consists of a p-n junction formed by very heavily doped p- and n-sides and a sharp transition in doping profile at the junction; and the diode operates based on inter-band tunneling of carriers across the p-n junction. Tunneling is possible as a result of the small width of the depletion region, on the order of 10 nanometers (nm, 1 nm=10⁻⁹ meters), which is significantly smaller than conventional p-n junctions. Further, tunnel diodes exhibit a negative differential resistance in forward bias, which has enabled a number of applications in high-frequency oscillators, amplifiers, and switches. A similar tunneling effect is used in tandem solar cells, which employ tunnel junctions to integrate different sub-cells, tunneling field-effect transistors (TFETs) which are one of the promising technologies for low-voltage operation and reduced energy consumption in electronics, as well as multi-junction laser diodes used as high efficiency and high power illumination sources in LIDAR and 3D sensing applications.

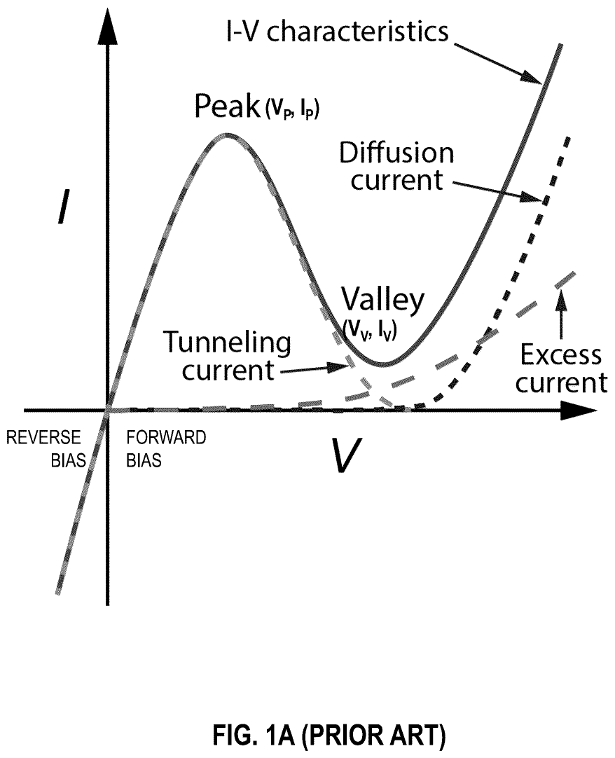

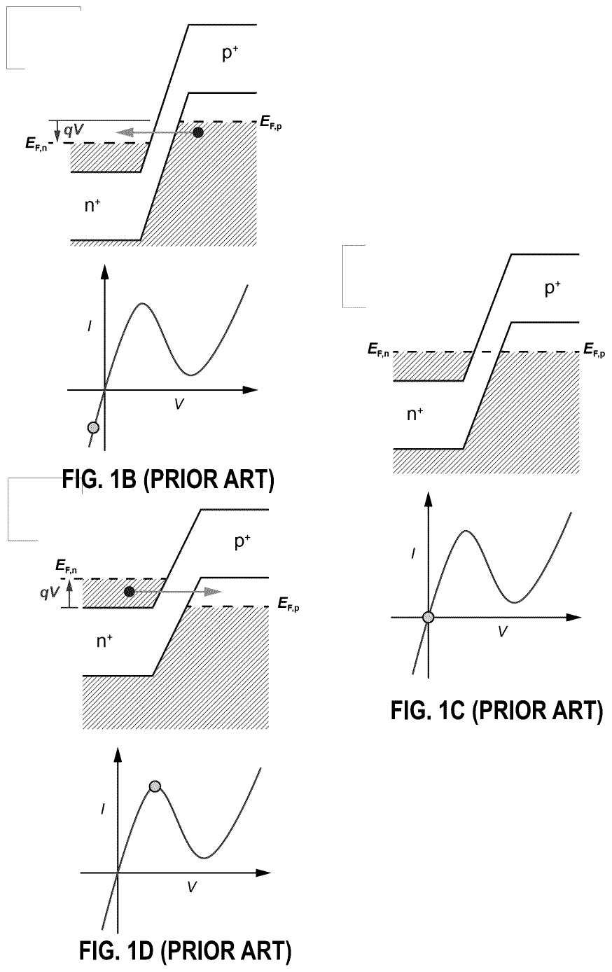

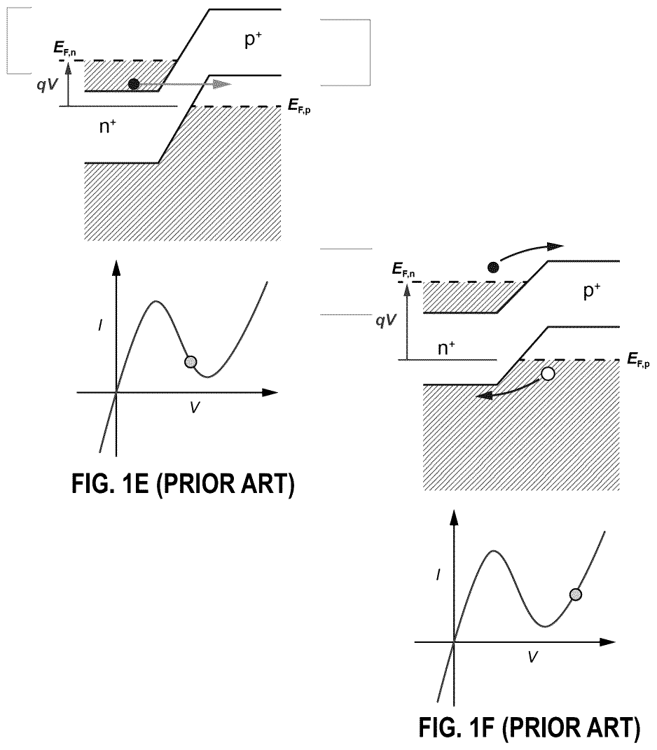

Here is briefly introduced various operating regimes of a tunnel diode. FIG. 1A is a schematic plot that illustrates example static current-voltage characteristic of a typical tunnel diode, used in various embodiments. As can be seen, in the reverse bias condition (negative applied voltage) the current increases monotonically (decreases in negative direction). Here positive current is current in the primary current direction. However, in the forward bias, the current first increases to a peak value of I_{P} (at voltage V_{P}), then decreases to a local minimum with a valley current of I_{V} (at voltage V_{V}), and then it increases monotonically with further increase in forward bias. The total current is the sum of three different components which are shown by dashed lines in FIG. 1A: (i) inter-band tunneling current, (ii) excess current, and (iii) diffusion current.

FIG. 1B through FIG. 1F show the simplified energy-band diagrams of a tunnel diode at absolute zero temperature and at various bias conditions, as used in various embodiments. The vertical direction indicates relative energy level and the horizontal direction indicates distance across the junction. The symbol n+ indicates heavily doped n-region; p+ indicates heavily doped p-region; E_{F,n} indicates Fermi level in the n region; E_{F,p} indicates Fermi level in the p region; V indicates bias voltage applied across the diode; and, q is the charge on an electron. At absolute zero all the energy states below the Fermi level set by the voltage and indicated by the horizontal dashed lines are fully occupied as indicated by grey shading. FIG. 1B shows a reverse bias state in which the p-side is at a higher voltage than the n-side. Because of high doping, the Fermi level is located within the conduction band in n-side and the valence band in p-side. An electron is depicted moving from the p side to the n side. At zero bias (thermal equilibrium), the Fermi level is constant across the junction (shown in FIG. 1C). Since there are no empty states (holes) below the Fermi level, and no filled states (electrons) above the Fermi level there is no tunneling current at zero bias. When a reverse or forward bias is applied, the electrons may tunnel from the conduction band to the valence band or vice versa (as shown in FIG. 1B and FIG. D, respectively). In forward bias, there exists a point where the common bands of energies of occupied states in n-side and unoccupied states in p-side are maximally aligned, at this point the tunneling current reaches its peak value (FIG. 1D). If the forward bias is further increased, the common energy bands decrease causing a decrease in the tunneling current (generating a region of negative differential resistance on the I-V curve) as shown in FIG. 1E. If the forward bias is further increased so that the edge of the n-side conduction band is aligned with the top of the p-side valence band, there are no available common energy bands and the tunneling current will reduce to negligible levels. At this point (valley of the I-V curve), the excess current will dominate which is mainly caused by carrier tunneling via energy states within the forbidden gap. With further increase in the bias, a normal diffusion current starts to flow as shown in FIG. 1F.

### 1.1 System Structures

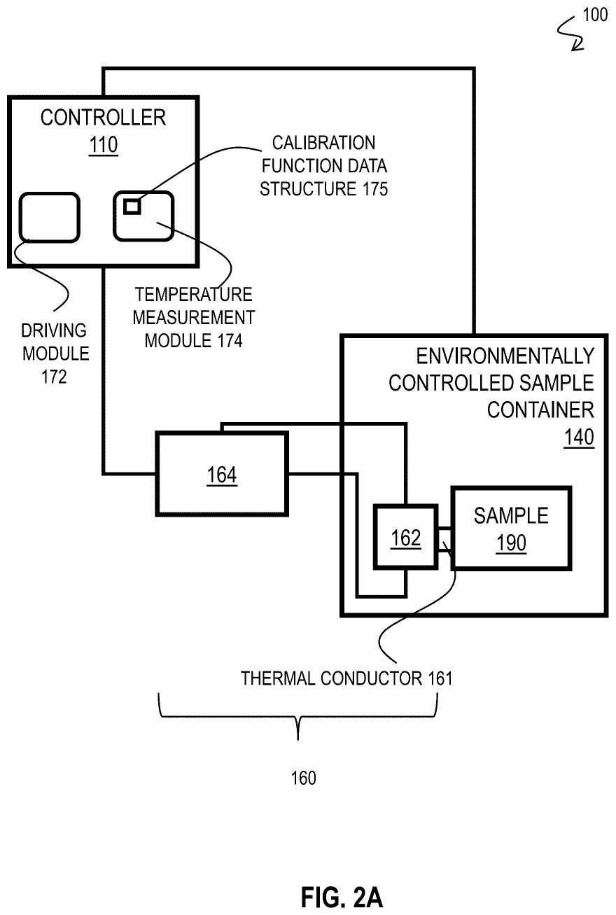

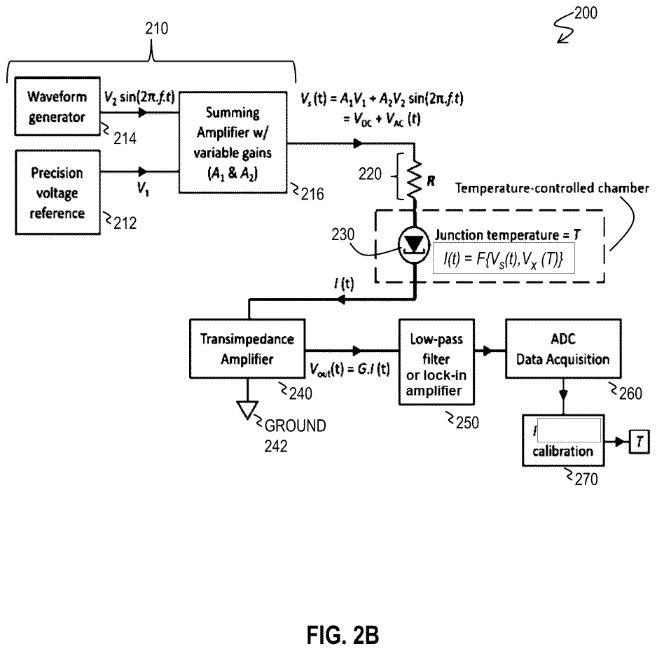

FIG. 2A is a block diagram that illustrates an example calorimeter system 100, according to an embodiment. A calorimeter is an apparatus for measuring the amount of heat involved in a chemical reaction or other process. Although sample 190 is depicted for purposes of illustration, sample 190 is not part of calorimeter system 100. The calorimeter system 100 includes ultra-high-resolution thermometer 160 (e.g., Tunneling-Diffusion Edge Sensor, TDES) and controller 110.

Ultra-high-resolution thermometer 160 includes semiconductor tunneling diode 162 configured to be placed in thermal contact with a sample, e.g., using thermal conductor 161, and support circuitry 164. The support circuitry 164 includes at least a voltage source, a resistor and a detector for an output current signal output from diode 162. Example components of support circuitry 164 are described in more detail below with reference to FIG. 2A.

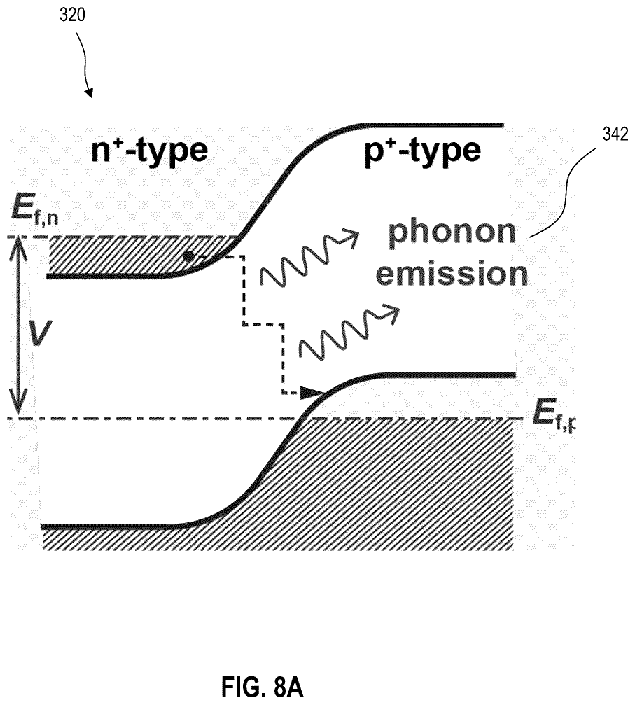

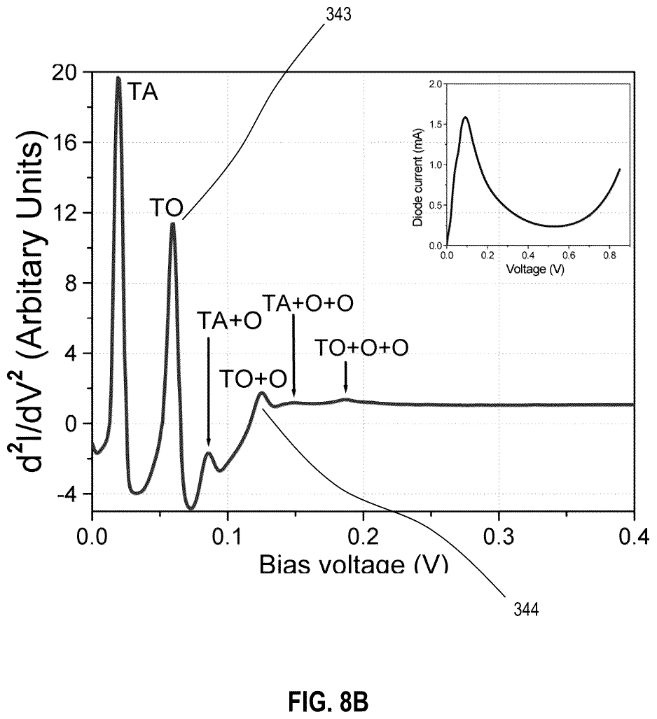

Controller 110 includes a module 172 configured to drive the support circuitry 164, e.g., to operate the voltage source and set values for any parameters for any components of circuitry 164. Controller 110 also includes a temperature measurement module 174 configured to derive temperature, temperature change, heat content or heat content changes, or some combination, for any sample 190 in thermal contact with diode 162. Module 174 includes a data structure 175 holding data that indicates a calibration function that relates the output current signal, directly or indirectly, to temperature. In some embodiments, controller 110 is a hardwired processor either integrated with support circuitry 164 or connected thereto by electrical connections. In some embodiments, controller 110 is a general-purpose computer system, such as depicted in FIG. 8, with modules 172 and 174 implemented as hardware ASICs, or software, or some combination.

In some embodiments, the diode 162, thermal conductor 161 and sample 190 are held in an environmentally controlled container 140, such as a vacuum chamber, an electric or magnetic field generator, a cryostat, an incubator or oven, a biological support well or test tube, or any other container for supporting sample 190 during whatever process temperature of the sample is being measured. Various calorimetry applications include samples involved in chemical processing, pharmaceutical, material processing and characterization, characterization of energy conversion and storage systems, and detection of energetic particles in high-energy physics applications. In some embodiments, driving module 172 of controller 110 is also configured to control the container 140 to establish or maintain a desired environment.

FIG. 2B is a block diagram that illustrates an example apparatus 200 for measuring temperature electronically using a semiconductor tunneling diode, according to an embodiment. The apparatus includes a semiconductor tunneling diode 230, a voltage source 210 and processor 270 configured to output a value of temperature with ultra-high resolution. In the depicted embodiment, the apparatus 200 also includes a transimpedance amplifier 240, a low pass filter or a lock-in amplifier or lock-in amplifier 250, and an analog to digital converter (ADC) and data acquisition module 260. The lock-in amplifier 250 is to extract the amplitude of current oscillation at excitation voltage (V_{AC}) frequency or harmonics of excitation voltage frequency. In various embodiments, all or part of ADC data acquisition module 260 and processor 270 are included in module 174 of controller 110.

The voltage source 210 is configured to provide a constant (direct current, DC) bias voltage designated V_{DC} and a temporally varying voltage V_{T}(t) that is a function of time, t, such as an alternating current, AC, voltage designated V_{AC}, both relative to electrical ground 242. In the illustrated embodiment, V_{AC} is depicted as having the functional form sin (2π f t) where t is time in time units and f is frequency in hertz and π is the ratio of a circle's circumference to its diameter; but, in other embodiments, other time varying or other oscillating voltages may be used including ramps, square waves and sawtooth signals. In various embodiments, one or more of the values for V_{DC}, V_{T}(t), V_{AC} and f is set by driving module 172 in controller 110.

In the illustrated embodiment, the voltage source 210 includes a precision voltage reference source 212, a waveform generator 214, and a summing amplifier with variable gains 216. The precision voltage reference source 212 is configured to produce a constant voltage V₁. The waveform generator 214 is configured to produce the time varying initial voltage Vᵢ(t), such as a ramp, square wave, sawtooth wave or an alternating current with frequency f. In the illustrated embodiment, the waveform generator produces an alternating current voltage waveform having the functional form Vᵢ(t)=V₂ sin(2π f t). The summing amplifier with variable gains 216, is configured to amplify the constant voltage Vᵢ by gain A₁, and the time varying initial voltage Vᵢ(t) by gain A₂ to produce a total voltage signal Vs given by Equation 1a.

$$Vs ( t ) = {A}_{1} {V}_{1} + {A}_{2} {V}_{i} ( t ) \qquad ( 1 a )$$

Which for the illustrated embodiment becomes Equation 1b.

$$Vs ( t ) = {A}_{1} {V}_{1} + {A}_{2} {V}_{2} sin ( 2 π f t ) \qquad ( 1 b )$$

Which can also be rewritten as Equation 1c.

$$Vs ( t ) = {V}_{DC} + {V}_{AC} ( t ) \qquad ( 1 c )$$

In various embodiments, one or more of the values for V₁, Vᵢ(t), V₂, A₁, A₂ and f is set by driving module 172 in controller 110.

Connected in series between the voltage source and the semiconductor tunneling diode 230 is a resistor 220 with resistance R selected to produce an appropriate negative resistance regime in the semiconductor tunneling diode 230, as described in more detail below. In some embodiments, a variable resistor (e.g., a rheostat or one of a plurality of selectable resistors) is used as resistor 220, and the resistance R is set by the driving module 172 in controller 110. In some embodiments, a shunt capacitor (not shown) is coupled in parallel to the resistor 220, or in parallel to the semiconductor tunneling diode 230, or parallel to both the resistor 220 and the semiconductor tunneling diode 230,

In particular, the resistor 220 defines a discontinuous edge between a tunneling current and a diffusion current of the semiconductor tunneling diode, with the discontinuous edge having a peak current and a valley current. The voltage source 210 is electrically connected in series with and up current of the resistor 220 and is configured to produce a constant voltage V_{DC} summed with a time oscillating voltage V_{AC}, with the time oscillating voltage V_{AC} causing an operating point of the semiconductor tunneling diode 230 to oscillate between the peak current and the valley current.

Semiconductor tunneling diode 230 is an embodiment of the diode 162 depicted in FIG. 1 and is configured to be placed in thermal contact with a sample in any environmentally controlled container 140. During calibration, the temperature of the container 140 or the sample 190 is known to sufficient precision to serve as a standard. For example, a known precise temperature source is used, or a temperature source or sample measured by a 1 calibrated thermometer is used in container 140, or some combination. For example, a high precision thermistor (a macroscopic sensor) is used, which is thermally connected to the test chamber (where the device under test (DUT) is also mounted). The thermistor is read out using a Wheatstone bridge to achieve a temperature resolution of <50 μK. However, this does not limit the characterization of the resolution of the DUT to 50 μK. The thermistor is only used to establish the calibration curve by introducing relatively large (several mK) temperature changes. Once the calibration curve is established, the DUT itself can detect potentially much smaller temperature changes than the calibration thermistor. There are at least two different well-stablished methods to achieve this goal: (i) obtaining the power spectral density of temperature fluctuations when the temperature of the sensor is stabilized; (ii) obtaining temperature sensing noise-floor by depositing gradually decreasing heating power on the sensor and measuring the resulted temperature rise using the sensor until the temperature rise is no longer detectable—as described in Weng et al. (2005), Reihani et al. (2022), and Sadat et al. (2011), the entire contents of which are hereby incorporated by reference as if fully set for the herein, except for terminology inconsistent with that used herein.

Semiconductor tunneling diodes typically have a heavily doped positive-to-negative (P-N) junction that is about 10 nm wide, which corresponds to about 100 Angstroms. The heavy doping results in a broken band gap, where conduction band electron states on the n-side are more or less aligned with valence band hole states on the p-side. They are usually made from germanium but can be made from gallium arsenide and silicon materials. The negative differential resistance, where current I drops with increasing voltage V between V_{P} and V_{V} shown in FIG. 1A, in part of their operating range allows them to function as oscillators and amplifiers, and in switching circuits. Their low capacitance allows them to function at microwave frequencies, far above the range of ordinary diodes and transistors. They have low output power and their radio frequency output is limited to few hundred milliwatts due to their small voltage swing. Example tunneling diodes are available from MP Series, M-PULSE MICROWAVE INC.™ San Jose, CA, USA; Part number IN3712, AMERICAN MICROSEMICONDUCTOR, INC™, New Jersey, USA; IN650 series, TEXAS INSTRUMENTS™, Dallas, TX.

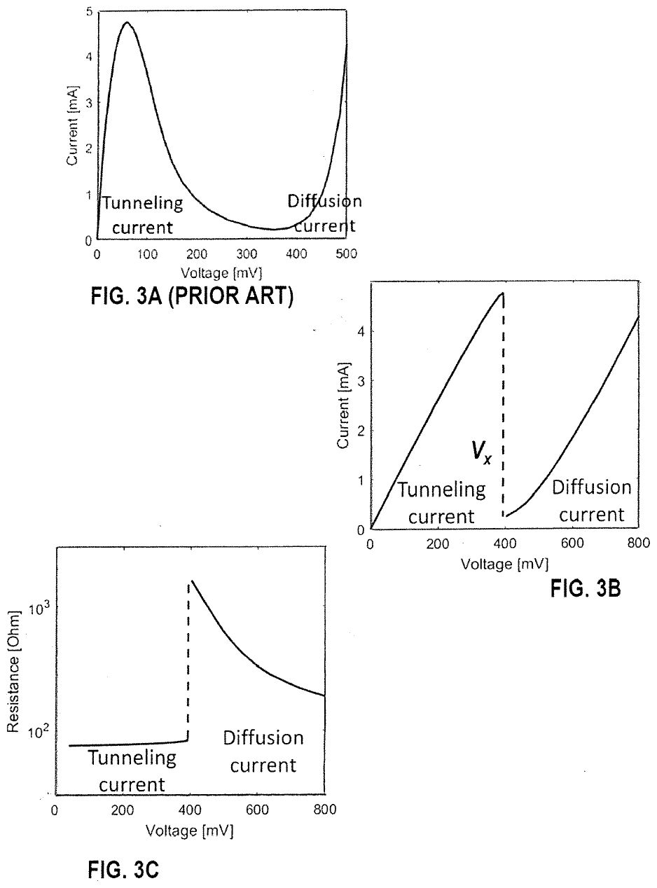

FIG. 3A through FIG. 3C are graphs that illustrate example outputs from a semiconductor tunneling diode, as used in various embodiments. The commercially available 4.7 mA/25 pF tunnel diode (IN3717 also known as the TD-3A available from TEKTRONIX™ of Beaverton Oregon) is used as an example. The stable DC current-voltage characteristic of the diode is shown in FIG. 3A, where the horizontal axis indicates applied voltage from a voltage source in millivolts (mV, 1 mV=10⁻³ Volts) and the vertical axis indicates current output by the diode in milliamperes (mA, 1 mA=10⁻³ Amperes). By Ohm's Law, the resistance R of a circuit component is the voltage V divided by the current I. The tunneling current regime occurs between 0 and about 350 mV, peaking at about 100 mV. After the applied voltage at the tunneling current peak the tunneling current decreases. Above about 350 mV, diffusion current regime commences that shows increasing current with increasing voltage.

When an appropriately chosen resistor 220 with resistance R is added in series with the stable tunnel diode, the characteristic changes and produces a discontinuous region at transition voltage Vₓ where transition between the tunneling and diffusion currents occurs. This is shown in FIG. 3B for R=70 Ohms and the IN3717 tunnel diode, where the horizontal axis indicates applied voltage from a voltage source in mV; and the vertical axis indicates current output by the diode in mA. Since, the current-voltage characteristic of tunneling diodes is temperature-dependent—as a result of the temperature dependence of band structure and carrier population—the transition voltage Vₓ is also temperature dependent. Depending on the diode material and structure, a rate of change of few to tens of mV/K is expected for Vₓ dependence on temperature T. That is, Vₓ is a function of temperature T, i.e., Vₓ(T), and the current output is a function F of Vₛ(t) and Vₓ(T). This relationship is expressed in Equation 2.

$$I ( t ) = F \{ {V}_{s} ( t ) , {V}_{x} ( T ) \} \qquad ( 2 )$$

The total resistance of the resistor 220 and diode 230 corresponding to FIG. 3B is shown in the semi-logarithmic plot of FIG. 3C. Therefore, the resistance of the tunnel diode at the discontinuous transition edge provides a very sensitive signal for resistive thermometry which would theoretically allow nanokelvin-resolution with microscale footprint at a broad range of temperatures including room temperature.

Because the total resistance as shown in FIG. 3C is discontinuous, it is not possible to obtain a continuously varying resistance versus temperature curve at the transition region (Vₛ≈Vₓ). To address this problem, a modulated bias measurement scheme is used as shown in FIG. 2B. As described above for the illustrated embodiment, the summing amplifier 216 is used to produce an AC plus DC sensing voltage (Vₛ) with a small AC amplitude (a few mV), and a larger DC component (or DC offset) chosen very close to the transition voltage Vₓ (e.g., 393 mV in FIG. 3B). The frequency f of the AC component is chosen based on the bandwidth of the final temperature measurement and would likely be in the range of hundreds of Hertz (Hz) to few kilohertz (kHz, 1 kHz=10³ Hz). As a result of adding an AC component to the applied bias across the diode and the series resistance, the operating point will continuously fluctuate between the peak and valley currents in FIG. 3B. The voltage of that transition, Vₓ, is extremely sensitive to temperature at an ultra-high temperature resolution.

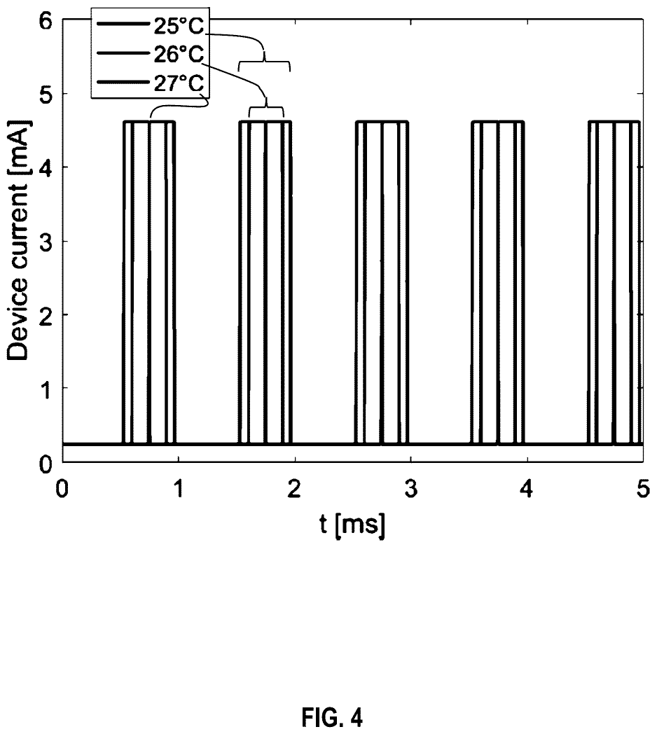

The resistor-diode device current is calculated in response to a sensing voltage with a peak-to-peak AC component of 10 mV (e.g., A₂V₂=5 mV) and a frequency f of 1 kHz, at three different temperatures of 25, 26, and 27° C. FIG. 4 is a graph that illustrates example output currents from a semiconductor tunneling diode at different temperatures when driven by a sum of a constant bias voltage and a temporally oscillating voltage, according to an embodiment. The horizontal axis indicates time t in milliseconds (ms, 1 ms=10⁻³ seconds) and the vertical axis indicates resistor-diode output current I in mA. As can be seen, the modulated sensing voltage creates a square wave current with a duty cycle that shows significant temperature-dependence. The duty cycle is a number-defined as the ratio of duration of pulse to the pulse period. In the illustrated embodiment, the amplitude of V_{AC} is very small and is only enough to jump back and forth from V_{P} to V_{V}. If the amplitude of V V_{AC} is larger, a partially sawtooth like waveform is produced. That is, a tunneling current is initiated at a time t1 when the sampling voltage V_{S}(t1) is below the transition voltage Vₓ and is cutoff sharply at a later time t2 when the sampling voltage V_{S}(t2) reaches the transition voltage Vx. At increasing temperatures, the transition voltage decreases and so the current I starts later in each cycle and ends sooner in each cycle. Thus at 25° C. the duty cycle is largest (widest in FIG. 4), decreases at 26° C., and is smallest (most narrow in FIG. 4) at 27° C. The system can be tuned to a different temperature range by changing the resistance R of resistor 220, or the properties of the semiconductor tunneling diode 230, with commensurate changes to the sampling voltage Vs DC and AC components output by voltage source 210, or some combination. For example, in some embodiments, the system is tuned to a different temperature by adjusting V_{DC}, and other parameters can remain constant.

Calibration data can then be collected and stored in data structure 175, which calibration data associates diode output current cycle width with temperature of the diode. In some embodiments, a theoretical or approximate function form F′ for F in Equation 2 is included in the calibration data and during calibration one or more parameters of the functional form F′ are determined that best match the temperature and current data. Subsequently, a new measurement of diode output current cycle width is used with the calibration in data structure 175 by module 174, e.g., in processor 270, to deduce temperature at the diode.

Determining diode output current duty cycle size experimentally is challenging. So, in some embodiments, the diode output current waveform, e.g., I(t) as plotted in FIG. 4, is converted to a voltage output signal, Vout, using a low-noise transimpedance amplifier 240. There are several commercial models available such as: SR570, from STANFORD RESEARCH SYSTEMS, Sunnyvale, CA, and AMP100, from THORLABS, Newton, NJ. In some embodiments, the amplifier is custom built to accommodate the currents expected for a given application. Vout is proportional to the output current I by a gain factor G, as expressed in Equation 3.

$$Vout ( t ) = GI ( t ) \qquad ( 4 )$$

In some embodiments, the value of G is set by the driving module 172 in controller 110. This Vout can be used for determining temperature at the diode much as described above. Calibration data can be collected and stored in data structure 175, which calibration data associates Vout cycle width with temperature of the diode. Subsequently, a new measurement of Vout cycle width is used with the calibration in data structure 175 by module 174, e.g., in processor 270, to deduce temperature at the diode.

Determining Vout cycle width experimentally is also challenging. So, in some embodiments, the Vout waveform, e.g., Vout(t), or the output current I(t) in embodiments that omit the transimpedance amplifier 240, is smoothed using low pass filter or lock-in amplifier 250, such as with a high-attenuation (4-pole Butterworth) filter to produce a smoothed voltage signal Vsmooth that is proportional by the factor G and filter attenuation factor H to the time-average of the device current shown in FIG. 4. In embodiments that omit the transimpedance amplifier 240, the low pass filter or lock-in amplifier 250 produces a smoothed current signal Ismooth that is proportional by the filter attenuation or gain factor H to the time-average of the device current shown in FIG. 4. A low-noise low-pass filter can be very easily fabricated, for example, a Butterworth filter with 4 or larger number of poles. Common commercial filters include: Model 3384, KROHN-HITE CORPORATION™, Brockton, MA among other models; SIM Series (such as SIM965) and SR600 Series, STANFORD RESEARCH SYSTEMS™, Sunnyvale, CA. These results are expressed in Equation 5a or 5b where LP represents the low pass operation.

$$Vsmooth ( t ) = HGLP \{ I ( t ) \} \qquad ( 5 a )$$

$$Ismooth ( t ) = HLP \{ I ( t ) \} \qquad ( 5 b )$$

In some embodiments, the value of H and other parameters of the low pass filter are set by the driving module 172 in controller 110. This Vsmooth or Ismooth can be used for determining temperature at the diode much as described above. Calibration data can be collected and stored in data structure 175, which calibration data associates Vsmooth or Ismooth with temperature of the diode. Subsequently, a new measurement of Vsmooth or Ismooth is used with the calibration in data structure 175 by module 174, e.g., in processor 270, to deduce temperature at the diode.

If the Vsmooth or Ismooth signal is still an analog signal then, in some embodiments, an analog to digital converter (ADC) and data acquisition module 280 is used to provide a digital series based on I(t), such as a digital time series of I(t) or Vout(t) or Ismooth(t) or Vsmooth(t), or some combination.

The processor 270, such as module 174 in controller 110, is configured to use the digital series with the calibration data in data structure 175 to output temperature at the diode as a function of time long compared to the one duty cycle. This temperature measurement is expected to exhibit ultra-high temperature resolution because of the sensitivity of Vₓ to such small changes in temperature.

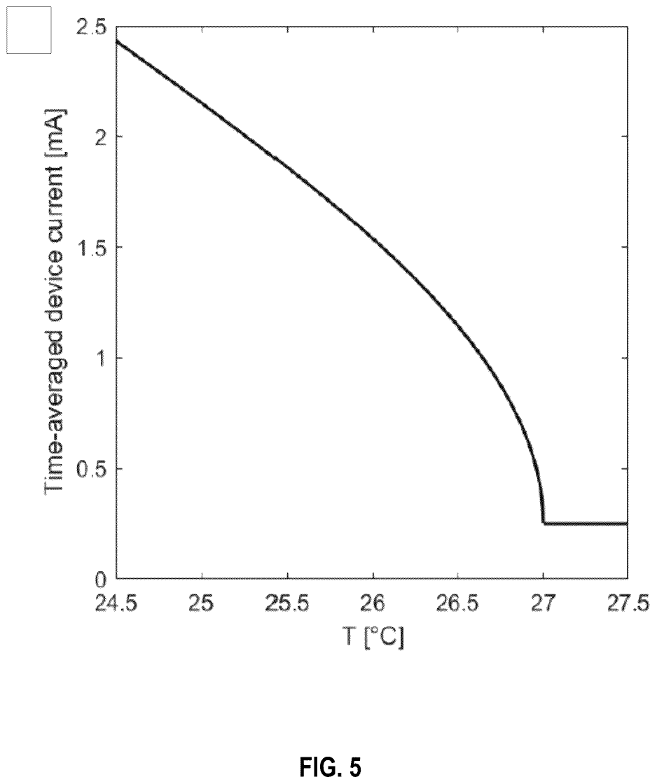

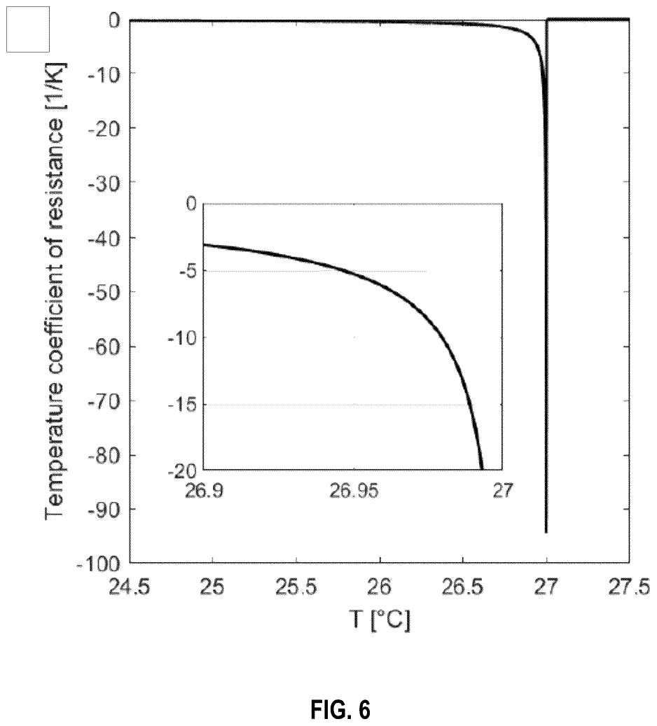

FIG. 5 and FIG. 6 are graphs that illustrates example calibration functions, according to an embodiment. A continuous time-averaged current as a function of temperature is shown in FIG. 5. The horizontal axis indicates temperature T in degrees Celsius; and, the vertical axis indicates time-averaged device current (e.g., Ismooth) in milliamperes. As can be seen, this approach resolves the issues with measuring a discontinuous transition voltage, Vₓ.

The correct precise temperature associated with each value of time-averaged current or used in other calibration functions, is determined using methods described above. For example, the thermometer as a device under test (DUT) is mounted in a temperature stabilized chamber with one or more thermal shields to reject environmental temperature fluctuations. The DUT is mounted in such a way that is itself thermally insulated as much as possible from the test chamber. Next, a heater is installed with a good thermal contact with the DUT which can locally heat the DUT. Next, a linear relationship between the amount of heat flow (q, unit of Watts) and the amount of temperature rise (ΔT) measured by DUT is established using Equation 6.

$$q = Gth Δ T \qquad ( 6 )$$

where Gth (units of Watts/Kelvin) is the thermal conductance. Once Gth is measured using the calibration thermometer (for example a thermistor) with relatively large ΔT values, then the same value of Gth can be used to obtain ΔT when much smaller q values are input to the system. With this technique, one can establish nanokelvin level resolution, with a calibration thermistor which has a resolution of only 50 to 100 μK.

The corresponding effective temperature coefficient of resistance (TCR) is plotted in FIG. 6. The horizontal axis indicates temperature in degrees Celsius and the vertical axis indicate of the temperature coefficient of resistance in units of factor per Kelvin. TCR (symbol is a) is defined using Equation 7.

$$α = ( 1 / R ) \times ( dR / dT ) \qquad ( 7 )$$

where R is the resistance of the component, and T is the temperature of the component. Here, R is the total resistance of tunnel diode and series resistance. As shown in the inset a TCR magnitude of above 500% K⁻¹ can be achieved over a temperature range of 50 mK, providing enough dynamic range for sensitive ultra-high-resolution thermometry.

Although processes, equipment, and data structures are depicted in FIG. 1 and FIGS. 2A, 2B as integral blocks in a particular arrangement for purposes of illustration, in other embodiments one or more processes or data structures, or portions thereof, are arranged in a different manner, on the same or different equipment, in one or more databases, or are omitted, or one or more different processes or data structures or equipment components are included.

### 1.2 Bolometer

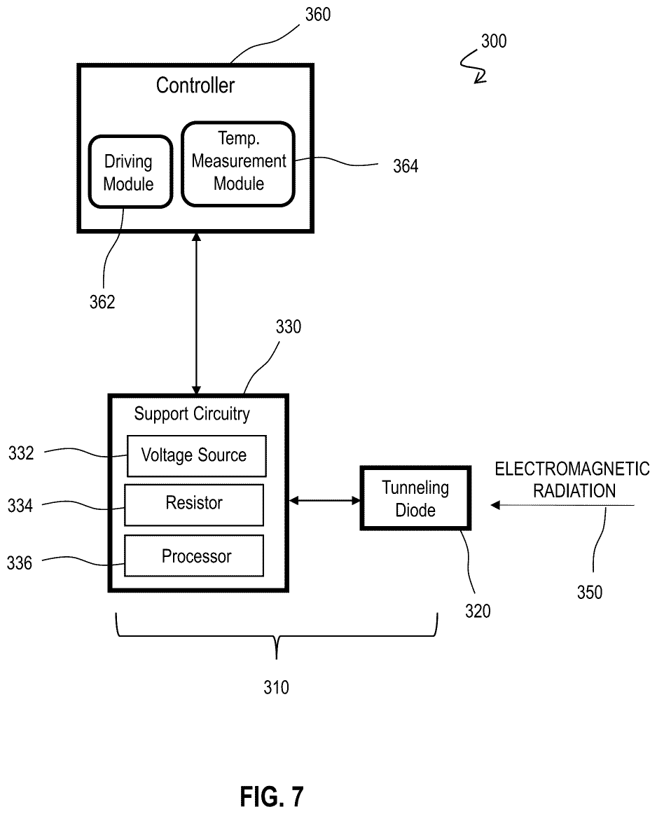

FIG. 7 is a block diagram that illustrates an example bolometer system 300, according to an embodiment. A first aspect of the bolometer system 300 includes an ultra-high-resolution thermometer 310 to enable broadband detection of electromagnetic radiation and may be widely used for infrared imaging as well as emerging applications for THz detection and spectroscopy. A broadband wavelength of the electromagnetic radiation 350 being detected may be in a range of 2 to 40 microns, for example. The ultra-high-resolution thermometer 310 is configured as a Tunneling-Diffusion Edge Sensor (TDES) as described above.

The ultra-high-resolution thermometer 310 relies on the temperature dependence of current in a semiconductor tunneling diode 320 when operated at the abrupt edge of interband tunneling current transition to diffusion current. The ultra-high-resolution thermometer 310 provides an increase of >100-fold in temperature sensitivity over state of the art (vanadium oxide) thermistors, which enables approaching the thermal fluctuation limit of bolometry at high bandwidth and at room temperature.

Support circuitry 330 is coupled to the semiconductor tunneling diode 320. The support circuitry 330 is based on support circuitry 164 as discussed above and includes at least a voltage source 332, a resistor 334 and a processor 336 for detecting a current signal output from the semiconductor tunneling diode 320. The semiconductor tunneling diode 320 is exposed to electromagnetic radiation 350. The resistor 334 is electrically connected in series with and up current of the semiconductor tunneling diode 320 to define a discontinuous edge between a tunneling current and a diffusion current of the semiconductor tunneling diode, with the discontinuous edge having a peak current and a valley current. The voltage source 332 is electrically connected in series with and up current of the resistor 334 and is configured to produce a constant voltage V_{DC} summed with a time oscillating voltage V_{AC}, with the time oscillating voltage V_{AC} causing an operating point of the semiconductor tunneling diode 320 to oscillate between the peak current and the valley current. The processor 336 is configured to determine temperature at the semiconductor tunneling diode 320 based at least in part on a current signal output from the semiconductor tunneling diode 320.

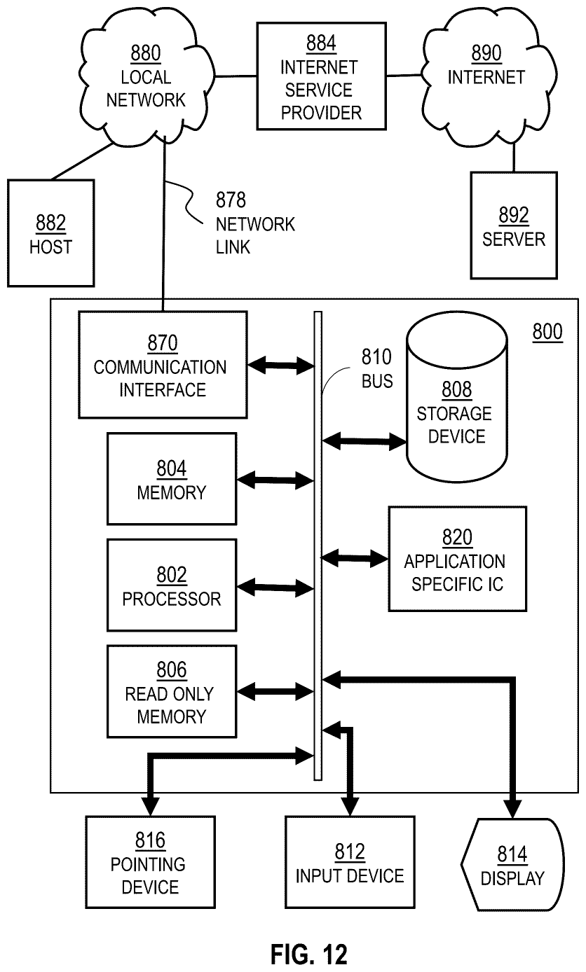

A controller 360 is coupled to the support circuitry 330. The controller 360 is based on controller 110 as discussed above and includes a driving module 362 configured to drive the support circuitry 330, e.g., to operate the voltage source and set values for any parameters for any components of the support circuitry 330. The controller 360 also includes a temperature measurement module 364 configured to derive temperature, temperature change, heat content or heat content changes, or some combination, for electromagnetic radiation 350 received by the semiconductor tunneling diode 320. The temperature measurement module 364 includes a data structure holding data that indicates a calibration function that relates the output current signal, directly or indirectly, to temperature. In some embodiments, the controller 310 is a hardwired processor either integrated with support circuitry 330 or connected thereto by electrical connections. In some embodiments, the controller 360 is a general-purpose computer system, such as depicted in FIG. 12, with modules 362 and 364 implemented as hardware ASICs, or software, or some combination.

### 1.2.1 Phono-Assisted Bolometer

A second aspect of the bolometer system 300 is to create tunneling junctions with strong optical phonon-assisted tunneling characteristics. This aspect of the bolometer system 300 may be referred to as a phonon-assisted microbolometer. In addition to bulk temperature sensing, the ultra-high-resolution thermometer 310 may be used for detection of non-equilibrium phonon occupation generated by light absorption (i.e., electromagnetic radiation). The electromagnetic radiation 350 received by the semiconductor tunneling diode 320 includes photons, which when received by the semiconductor tunneling diode 320, emits phonons in response to the photons. The phonons assist in tunneling of particles through the positive-to-negative (P-N) junction of the semiconductor tunneling diode 320.

A phonon-assisted microbolometer will benefit from non-equilibrium occupation of energetic optical phonons generated during the light absorption process, and can detect the incident radiation without a need for a change in the bulk temperature of the bolometer detector. Theoretically, this phonon-assisted process can exceed the thermal fluctuation limit. In addition, since there is no need for bulk temperature change of the detector, the detection rate will not be limited to the thermal time constant of the bolometer, allowing operation at significantly higher bandwidth.

Tunnel diodes are formed at the junction of degenerately doped p- and n-type semiconductors with sharp doping profiles. FIG. 1A shows the typical I-V characteristic of a tunnel diode with contributions from interband tunneling current, forward diffusion current, and excess current. The negative differential resistance (NDR) characteristic has enabled tunnel diode applications in high-frequency oscillators and amplifiers. The temperature dependence of I-V characteristic in tunnel diodes shows significant variation depending on device composition. The diffusion current always shows an increase at higher temperatures due to enhancement of normal forward injection.

However, the behavior of interband tunneling current is more complex and depends on temperature dependences of bandgap, effective masses, phonon occupation, and Fermi functions. A Fermi function is a probability distribution function for charge carriers. The Fermi function determines the probability that an energy state (E) is filled with an electron when the material being worked with is under equilibrium conditions. This leads to an increasing or decreasing behavior of tunneling current as a function of temperature depending on the exact composition and dopants, but also provides large flexibility in tuning the temperature dependence. The phonon-assisted microbolometer 300 relies on the temperature dependence of I-V characteristic of the tunnel diode when operated in a specific circuit to achieve high temperature sensitivity.

In a tunnel diode made from indirect-bandgap semiconductors, the interband tunneling current is dominated by indirect phonon-assisted tunneling and has contributions from single or multi-phonon scattering processes at different bias levels. FIG. 8A shows the band diagram of a tunnel diode 320 in forward bias which demonstrates indirect tunneling with emission of two phonons 342, for example.

As an example, FIG. 8B shows the phonon-assisted tunneling spectrum in a silicon Esaki diode. A TO process 343 occurs at 60 mV that includes emission of a transverse-optic (TO) in the NDR region. A TO+O process 344 occurs at 121 mV that includes emission of a transverse-optic (TO) and an optical phonon (O) in the NDR region. Such processes are the basis of the phonon-assisted detection technique, as light absorption creates non-equilibrium optical phonon population which may be detected by monitoring the current in the NDR region of the tunnel diode characteristic.

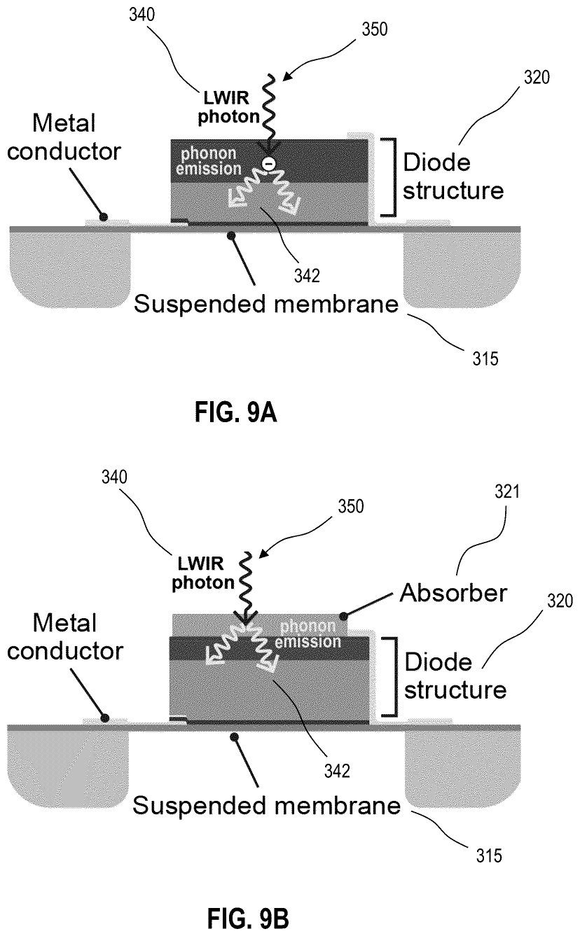

In FIG. 9A, optical phonon scattering is based on the semiconductor tunneling diode 320 being heavily-doped. The doping may be n⁺-Germanium (Ge), for example, with a free carrier density greater than or equal to 10¹⁸ cm⁻³ range. A heavily-doped semiconductor acts as an absorber and demonstrates high absorption by free-carrier excitation, subsequently relaxed by optical phonon scattering.

The absorber (i.e., heavily-doped semiconductor tunneling diode 320) will enhance the detection of the wavelength of light that's hitting it. And a secondary feature is that it can generate phonons 342. The phonons 342 make the semiconductor tunneling diode 320 even more sensitive. Light absorption leads to accumulation of optical phonons in the material which are relaxed in ~10 ps by exchanging energy with acoustic phonons carrying the absorbed optical energy away from the light absorption region (i.e. via heat conduction).

The heavily-doped semiconductor absorbs photons 340 in the electromagnetic radiation 350 and emits phonons 342 in response to the absorbed photons 340, with the phonons 342 assisting in tunneling of particles through a positive-to-negative (P-N) junction of the semiconductor tunneling diode 320. The semiconductor tunneling diode 320 is on a suspended thin-film membrane 315. The thin-film may be silicon nitride, for example. The suspended membrane 315 is to minimize heat conduction to the underlying substrate, essentially to minimize thermal conductance.

In FIG. 9B, optical phonon scattering is based on the semiconductor tunneling diode 320 having an absorber layer 321 exposed to the electromagnetic radiation 350. The absorber layer 321 is configured to enhance detection of the electromagnetic radiation 350 by absorbing the electromagnetic radiation 350. A secondary effect of the absorber layer 321 is to absorb photons 340 in the electromagnetic radiation 350 and emit phonons 342 in response to the absorbed photons 340, with the phonons 342 assisting in tunneling of particles through a positive-to-negative (P-N) junction of the semiconductor tunneling diode 320.

The absorber layer 321 may be silicon nitride (SiNₓ), silicon dioxide (SiO₂), barium titanate (BaTiO₃), or any polar dielectric, for example. The absorber layer 321 enhances the detection of the wavelength of light that's hitting it. And a secondary feature is that it can generate phonons 342. The phonons 342 makes the semiconductor tunneling diode 320 even more sensitive.

In summary, there are two modes of detection of electromagnetic energy 350. A first mode is based on the thermal mode of detection, which relies on bulk temperature change of the semiconductor tunneling diode 320 without any absorber enhancements. A second mode is based on a phonon-assisted detection, which does not rely on the bulk temperature change. Instead, it relies on emission of phonons 342 from an absorber. One embodiment of the absorber may be configured as a heavily-doped semiconductor tunneling diode 320, as shown in FIG. 9A. Another embodiment of the absorber is an absorber layer 321 placed on the semiconductor tunneling diode 320, as shown in FIG. 9B.

### 1.2.2 Theory of Phonon-Assisted Bolometry

Light absorption in many materials involves emission of energetic optical phonons. This includes polar dielectrics supporting phonon-polaritons in MW-LWIR range, such as SiNₓ, SiO₂, and BaTiO₃. A second class of materials of interest is heavily-doped semiconductors, such as n⁺-Ge (free carrier density at least equal to 10¹⁸ cm⁻³ or greater) that demonstrate high absorption by free-carrier excitation, subsequently relaxed by optical phonon scattering. In both cases, light absorption leads to accumulation of optical phonons in the material which are relaxed in ~10 ps by exchanging energy with acoustic phonons carrying the absorbed optical energy away from the light absorption region (i.e. via heat conduction).

Phonon-assisted tunneling in Esaki diodes made from indirect bandgap semiconductors dominate the total junction current. A model for indirect tunneling is Kane's model which describes the phonon-assisted tunneling current density (J) between the conduction band valley and the valence band as:

$$J = {\sum }_{i} C [ ( {N}_{i} + 1 ) ( {P}_{i} ( fe ) {S}_{i} ( fe ) - {P}_{i} ( re ) {S}_{i} ( re ) ) + {N}_{i} ( {P}_{i} ( fa ) {S}_{i} ( fa ) - {P}_{i} ( ra ) {S}_{i} ( ra ) ) ] \qquad ( 8 )$$

The sum is over phonon modes i which satisfy the selection rules (energy and momentum) for transition between the appropriate energy levels. In Ge tunnel diodes, the transition is between the (000) valence band and (111) conduction band valleys. The quantity C is a constant given by effective masses, bandgap and average junction field. Nᵢ is the phonon occupation number for the i^{th} phonon. Pᵢ are the tunneling probabilities and Sᵢ are the integrals over electron energy distribution functions. The symbols f and r stand for forward and reverse tunneling, and the symbols e and a stand for phonon emission and absorption, respectively.

Equation 8 provides insight into the effect of phonon occupation on the tunneling current. At sufficiently low temperatures (e.g., 4.2 K), based on the Bose-Einstein (B-E) statistics, most phonon occupations are very low (i.e. Nᵢ~0), leading to contribution only from phonon emission processes. At higher temperatures where the phonon modes are sufficiently excited both absorption and emission contribute to the tunneling current. Since both absorption and emission contributions scale with phonon occupation, an increase in the tunneling current with increase in the phonon occupation is expected. Since the Debye temperature for most semiconductors used for tunnel diode fabrication (for example Ge and Si) are above room temperature, the occupation of optical phonons is below unity at room temperature. For example, the occupation number for TO in Ge is N_{TO}=0.2 and in Si is N_{TO}=0.12. Unlike the Fermi-Dirac distribution, the B-E statistics does not limit the occupancy to unity, and hence the phonon occupation can be pumped above unity under non-equilibrium conditions (e.g. during light absorption). This may advantageously be used as a method for photon detection without a need for bulk temperature change of the bolometer.

Based on the selection rule, the applied bias across the junction can select the exact phonon modes that contribute most to indirect tunneling. For Ge Esaki diodes, a TO-assisted transition occurs close to the peak current and a TO+TO-assisted transition occurs in the NDR region. For Si Esaki diodes, TO+O-assisted transition occurs close to peak current, and TA+O+O and TO+O+O-assisted transitions occur in the NDR region. Therefore, both Si and Ge may be used to alter tunneling current based on optical phonon occupation. Given that in the TDES method described above, the applied bias sweeps the vicinity of the NDR region, and a change in the diode current is expected upon change in the optical phonon occupancy.

### 1.3 Microfluidic Calorimeter

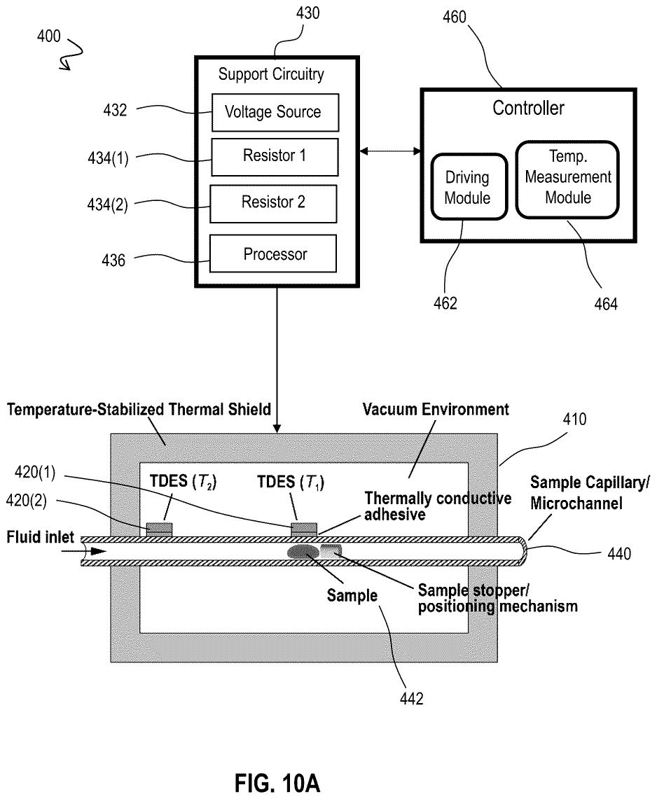

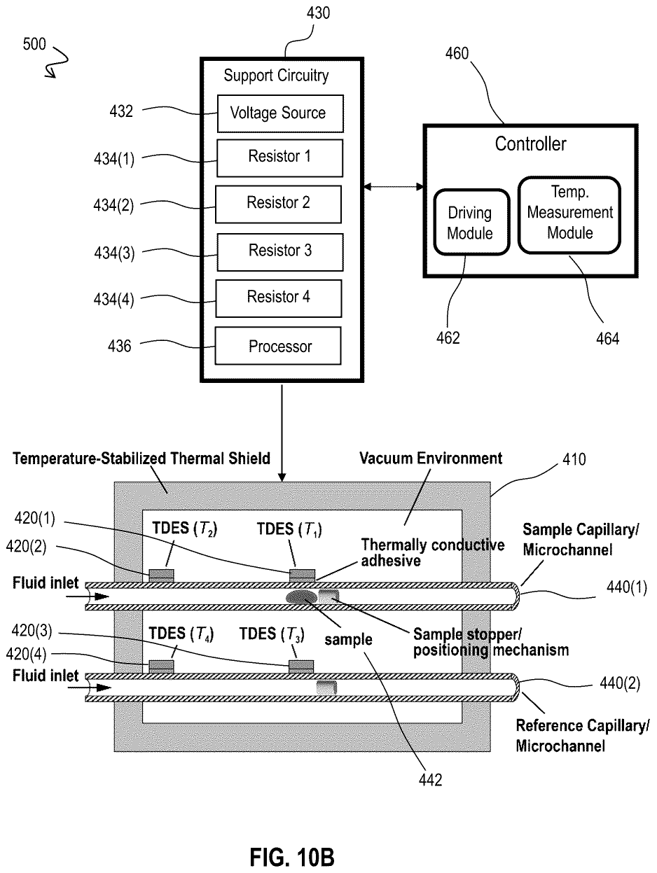

FIG. 10A is a block diagram that illustrates an example isothermal microfluidic calorimeter system 400, according to an embodiment. The isothermal microfluidic calorimeter system 400 includes at least one temperature-controlled thermal shield 410, and a microfluidic channel 440 in thermal contact with the at least one temperature-controlled thermal shield 410. The microfluidic channel 440 comprises a fluid or gas in contact with a sample 442. The fluid or gas within the microfluidic channel 440 is needed to react with the sample or support the operation of the sample 442. Depending on the sample type, a vacuum may be provided instead of the fluid or gas. The at least one temperature-controlled thermal shield 410 provides a vacuum environment for the microfluidic channel 440.

The sample 442 may be, for example, biological, a single cell, a solution, a nanomaterial or a powder. When the sample 442 is biological, the microfluidic calorimeter system 400 specifically measures the heat output of the biological sample, for example, due to metabolic activities or reacting to the environment. Specifically, the microfluidic calorimeter system 400 would have such a high resolution to probe heat output from a single cell. This could, for example, be used to detect cancer or study aging mechanisms on a single cell sample. In general, measurement of metabolic activity is valuable and used in many different areas of biology and medicine.

The microfluidic calorimeter system 400 includes support circuitry 430 interfacing with the at least one temperature-controlled thermal shield 410. The support circuitry 430 is based on support circuitry 164 as discussed above. The support circuitry 430 includes a first semiconductor tunneling diode 420(1) coupled to the microfluidic channel 440 and placed adjacent the sample 442. The support circuitry 430 includes a first electrical resistor 434(1) electrically connected in series with and up current of the first semiconductor tunneling diode 420(1) to define a discontinuous edge between a tunneling current and a diffusion current of the first semiconductor tunneling diode 420(1), with the discontinuous edge having a peak current and a valley current.

A second semiconductor tunneling diode 420(2) is coupled to the microfluidic channel 440 and is spaced away from the sample 442. The support circuitry 430 further includes a second electrical resistor electrically 434(2) connected in series with and up current of the second semiconductor tunneling diode 420(2) to define a discontinuous edge between a tunneling current and a diffusion current of the second semiconductor tunneling diode 420(2), with the discontinuous edge having a peak current and a valley current.

A voltage source 432 within the support circuitry 430 is electrically connected in series with and up current, respectively, of the first and second electrical resistors 420(1), 420(2) and is configured to produce a constant voltage V_{DC} summed with a time oscillating voltage V_{AC}, with the time oscillating voltage V_{AC} causing an operating point of the first and second semiconductor tunneling diodes 420(1), 420(2) to respectively oscillate between the peak current and the valley current.

A processor 436 within the support circuitry 430 is configured to determine respective temperatures at the first and second semiconductor tunneling diodes 420(1), 420(2) based at least in part on a respective current signal output from the first and second semiconductor tunneling diodes 420(1), 420(2), with the respective temperatures being used by the processor to determine a heat flow released by the sample.

A controller 460 is coupled to the support circuitry 330. The controller 460 is based on controller 110 as discussed above and includes a driving module 462 configured to drive the support circuitry 430, e.g., to operate the voltage source and set values for any parameters for any components of the support circuitry 430. The controller 460 also includes a temperature measurement module 464 configured to set the temperature of the calorimeter, ramp the temperature, measure the temperatures and temperature change in response to heat release from the sample, measure heat flow released from or absorbed by the sample, or some combination as released by the sample.

The first and second semiconductor tunneling diodes 420(1), 420(2) thus allow temperature measurements on multiple locations to determine the heat flow released by the sample 442. A heat transfer model relates the temperature measurements to the heat flow being released by the sample 442. For the isothermal microfluidic calorimeter system 400 under steady state heat release conditions, the heat flow from the sample 442 can be identified as:

$$q = {G}_{1} \cdot ( {T}_{1} - {T}_{2} ) \qquad ( 9 )$$

Where G₁ is the total thermal conductance of the microfluidic channel 440 to the surrounding environment.

Similarly, a differential isothermal or a differential scanning microfluidic calorimeter system 500 is constructed by adding a reference microfluidic channel 440(2), as shown in FIG. 10B. The reference microfluidic channel 440(2) is empty or holds a blank sample that does not release heat, and is used as a reference to reject common mode thermal perturbations. The reference microfluidic channel 440(2) is in thermal contact with the at least one temperature-controlled thermal shield 410, and comprises a fluid or gas or vacuum.

The microfluidic calorimeter 500 further includes a third semiconductor tunneling diode 420(3) coupled to the reference microfluidic channel 440(2), and a third electrical resistor 434(3) electrically connected in series with and up current of the third semiconductor tunneling diode 420(3) to define a discontinuous edge between a tunneling current and a diffusion current of the third semiconductor tunneling diode, with the discontinuous edge having a peak current and a valley current.

A fourth semiconductor tunneling diode 420(3) is coupled to the reference microfluidic channel 440(2) and spaced away from the third semiconductor tunneling diode 420(3). A fourth electrical resistor 434(4) is electrically connected in series with and up current of the fourth semiconductor tunneling diode 420(4) to define a discontinuous edge between a tunneling current and a diffusion current of the fourth semiconductor tunneling diode 420(4), with the discontinuous edge having a peak current and a valley current.

The voltage source 432 is now electrically connected in series with and up current of the third and fourth electrical resistors 434(3), 434(4) and is configured to produce a constant voltage V_{DC} summed with a time oscillating voltage V_{AC}, with the time oscillating voltage V_{AC} causing an operating point of the third and fourth semiconductor tunneling diodes to respectively oscillate between the peak current and the valley current. The processor 436 is further configured to determine respective temperatures at the third and fourth semiconductor tunneling diodes 420(3), 420(4) based at least in part on a respective current signal output from the third and fourth semiconductor tunneling diodes 420(3), 420(4).

The first, second, third and fourth semiconductor tunneling diodes 420(1), 420(2), 420(3), 420(4) thus allow temperature measurements on multiple locations to determine the heat flow released by the sample 442. Like above, a simple heat transfer model relates the temperature measurements to the heat flow released by the sample 442 located below T₁. For example, for a differential isothermal microfluidic calorimeter under steady state heat release conditions, the heat flow from the sample can be identified as:

$$q = {G}_{1} \cdot ( {T}_{1} - {T}_{2} ) - {G}_{2} \cdot ( {T}_{3} - {T}_{4} ) \qquad ( 10 )$$

Where G₁ and G₂ are the total thermal conductances of the primary and reference microfluidic channels 440(1), 440(2) to the surrounding environment, respectively.

The environment surrounding the microfluidic channel 440(1) and the reference microfluidic channel 440(2) is maintained at high vacuum to minimize gas conductance from the respective microfluidic channels 440(1), 440(2) to the at least one thermal shield 410 which leads to improved temperature stability and heat flow resolution.

### 1.4 Method

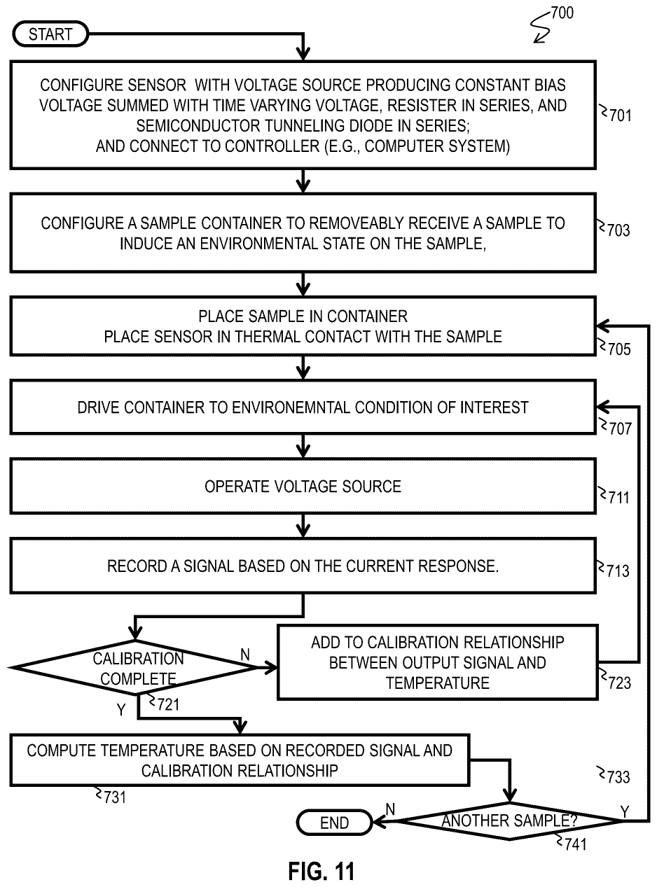

FIG. 11 is a flowchart that illustrates an example method for making and using the system of FIG. 1, according to an embodiment. Although steps are depicted in FIG. 11 as integral steps in a particular order for purposes of illustration, in other embodiments, one or more steps, or portions thereof, are performed in a different order, or overlapping in time, in series or in parallel, or are omitted, or one or more additional steps are added, or the method is changed in some combination of ways.

In step 701, an apparatus 200 is configured with at least a voltage source 210 and a resistor 220 in series with a semiconductor tunneling diode 230, 162 and a processor 270 to convert output from the diode to a value for temperature at the diode. In some embodiments, the apparatus also includes one or more of a transimpedance amplifier 240, a low pass filter or lock-in amplifier 250, an ADC data acquisition module 260 and a controller 110 configured with module 172 to drive the voltage source to produce a time varying voltage added to a steady voltage selected at or near a transition voltage of the diode at an expected temperature for which precise temperature changes are to be measured. In some embodiments, the apparatus 200 includes a thermal conductor 162 configured to bring the diode into thermal contact with a sample.

In step 703 a sample container 140 is configured to removably receive a sample 190 and to provide environmental conditions for the sample, such as a heat source, magnetic or electrical field, vacuum, pressure, chemical solution, biological support or buffering fluid.

In step 705 a sample 190 is placed in the container 140 and placed in thermal contact with the semiconductor tunneling diode 162 of the sensor, e.g., by contacting thermal conductor 161.

In step 707, the controller 110 is operated to drive the container 140 to provide the environmental condition of interest for the sample 190.

In step 711, the controller 110 module 172 drives the voltage source 210 to provide eh constant and time varying components of the sample voltage V_{S}.

In step 713, a signal such as I(t) or Vout(t) or Ismooth(t) or Vsmooth(t), or some combination, based on the current output I(t), is recorded, e.g., by ADC data acquisition module 260

In step 721 it is determined whether calibration is complete. If not, control passes to step 723 to add to the calibration relationship between output signal and temperature by storing data in data structure 175. For example another point is added to the traces in FIG. 5 and FIG. 6. Control then passes to step 707 and following steps to drive container 140 to next condition of interest, such as the next temperature for collection of calibration data.

If it is determined in step 721 that calibration is complete, then control passes to step 731. In step 731, the temperature at the tunneling diode is computed and output based on the recorded signal and the calibration relationship stored in data structure 175. Control then passes to step 741.

In step 741, it is determined if there is another sample measurement to make, e.g., the same sample at a different time or a different sample. If so control passes back to step 705 and following, described above. Otherwise, the process ends.

### 2. EXAMPLE EMBODIMENTS

According to an example embodiment, a semiconductor tunneling diode 230 is a tunnel diode device made from III-V semiconductors (InGaAs), and has footprint dimensions of 10 μm×10 μm. When operated using the measurement apparatus and methods described herein, the TCR of FIG. 6 is projected and a thermometry noise floor including the noise sources in the sensor and readout electronics is estimated to be ~15 nK/VHz.

The described technology is compatible with commercially available microfabrication techniques and can be integrated on a microscale or even nanoscale footprint if needed. Indeed, a sensor with a footprint of (10 μm)² can easily be fabricated using standard approaches. The sensor can be read using standard analog electronics which are both cost effective, compact, and easy to integrate with other electronic components for example in a thermal camera. This is an advantage over other existing nanokelvin-resolution optical or photonic schemes.

The described techniques provide advances in bolometry, the measurement of infrared radiation. The TDES can improve the sensitivity of bolometers by 1-2 orders of magnitude. For example, in thermal cameras the “Noise Equivalent Temperature Difference (NETD)” indicates the smallest temperature difference that a thermal camera can detect. For the highest resolution uncooled sensors in the mid-infrared range, it is ~30 mK. The TDES sensor has the potential to reduce the NETD to ~1 mK or lower depending on the design. The TDES can improve the sampling rate. Common mid-infrared sensors have a sampling rate <10 Hz. This can be improved by leveraging the high sensitivity of TDES. TDES enables broadband detection without a need for cooling of the sensor. Given its high resolution, a TDES based microbolometer can achieve broadband detection close to the ideal thermal detectors and compete with many other cooled semiconductor-based sensors in the mid infrared (MIR) and far infrared (FIR) range.

The described techniques provide advances in calorimetry. The TDES can improve the resolution of existing sensitive calorimeters by 1 to 3 orders of magnitude. TDS can provide improvement in the detection time of the instrument as a result of small thermal capacitance of the sensor.

### 3. COMPUTATIONAL HARDWARE OVERVIEW

FIG. 12 is a block diagram that illustrates a computer system 800 upon which an embodiment of the invention may be implemented. Computer system 800 includes a communication mechanism such as a bus 810 for passing information between other internal and external components of the computer system 800. Information is represented as physical signals of a measurable phenomenon, typically electric voltages, but including, in other embodiments, such phenomena as magnetic, electromagnetic, pressure, chemical, molecular atomic and quantum interactions. For example, north and south magnetic fields, or a zero and non-zero electric voltage, represent two states (0, 1) of a binary digit (bit). Other phenomena can represent digits of a higher base. A superposition of multiple simultaneous quantum states before measurement represents a quantum bit (qubit). A sequence of one or more digits constitutes digital data that is used to represent a number or code for a character. In some embodiments, information called analog data is represented by a near continuum of measurable values within a particular range. Computer system 800, or a portion thereof, constitutes a means for performing one or more steps of one or more methods described herein.

A sequence of binary digits constitutes digital data that is used to represent a number or code for a character. A bus 810 includes many parallel conductors of information so that information is transferred quickly among devices coupled to the bus 810. One or more processors 802 for processing information are coupled with the bus 810. A processor 802 performs a set of operations on information. The set of operations include bringing information in from the bus 810 and placing information on the bus 810. The set of operations also typically include comparing two or more units of information, shifting positions of units of information, and combining two or more units of information, such as by addition or multiplication. A sequence of operations to be executed by the processor 802 constitutes computer instructions.

Computer system 800 also includes a memory 804 coupled to bus 810. The memory 804, such as a random-access memory (RAM) or other dynamic storage device, stores information including computer instructions. Dynamic memory allows information stored therein to be changed by the computer system 800. RAM allows a unit of information stored at a location called a memory address to be stored and retrieved independently of information at neighboring addresses. The memory 804 is also used by the processor 802 to store temporary values during execution of computer instructions. The computer system 800 also includes a read only memory (ROM) 806 or other static storage device coupled to the bus 810 for storing static information, including instructions, that is not changed by the computer system 800. Also coupled to bus 810 is a non-volatile (persistent) storage device 808, such as a magnetic disk or optical disk, for storing information, including instructions, that persists even when the computer system 800 is turned off or otherwise loses power.

Information, including instructions, is provided to the bus 810 for use by the processor from an external input device 812, such as a keyboard containing alphanumeric keys operated by a human user, or a sensor. A sensor detects conditions in its vicinity and transforms those detections into signals compatible with the signals used to represent information in computer system 800. Other external devices coupled to bus 810, used primarily for interacting with humans, include a display device 814, such as a cathode ray tube (CRT) or a liquid crystal display (LCD), for presenting images, and a pointing device 816, such as a mouse or a trackball or cursor direction keys, for controlling a position of a small cursor image presented on the display 814 and issuing commands associated with graphical elements presented on the display 814.

In the illustrated embodiment, special purpose hardware, such as an application specific integrated circuit (IC) 820, is coupled to bus 810. The special purpose hardware is configured to perform operations not performed by processor 802 quickly enough for special purposes. Examples of application specific ICs include graphics accelerator cards for generating images for display 814, cryptographic boards for encrypting and decrypting messages sent over a network, speech recognition, and interfaces to special external devices, such as robotic arms and medical scanning equipment that repeatedly perform some complex sequence of operations that are more efficiently implemented in hardware.

Computer system 800 also includes one or more instances of a communications interface 870 coupled to bus 810. Communication interface 870 provides a two-way communication coupling to a variety of external devices that operate with their own processors, such as printers, scanners and external disks. In general, the coupling is with a network link 878 that is connected to a local network 880 to which a variety of external devices with their own processors are connected. For example, communication interface 870 may be a parallel port or a serial port or a universal serial bus (USB) port on a personal computer. In some embodiments, communications interface 870 is an integrated services digital network (ISDN) card or a digital subscriber line (DSL) card or a telephone modem that provides an information communication connection to a corresponding type of telephone line. In some embodiments, a communication interface 870 is a cable modem that converts signals on bus 810 into signals for a communication connection over a coaxial cable or into optical signals for a communication connection over a fiber optic cable. As another example, communications interface 870 may be a local area network (LAN) card to provide a data communication connection to a compatible LAN, such as Ethernet. Wireless links may also be implemented. Carrier waves, such as acoustic waves and electromagnetic waves, including radio, optical and infrared waves travel through space without wires or cables. Signals include man-made variations in amplitude, frequency, phase, polarization, or other physical properties of carrier waves. For wireless links, the communications interface 870 sends and receives electrical, acoustic or electromagnetic signals, including infrared and optical signals, that carry information streams, such as digital data.

The term computer-readable medium is used herein to refer to any medium that participates in providing information to processor 802, including instructions for execution. Such a medium may take many forms, including, but not limited to, non-volatile media, volatile media and transmission media. Non-volatile media include, for example, optical or magnetic disks, such as storage device 808. Volatile media include, for example, dynamic memory 804. Transmission media include, for example, coaxial cables, copper wire, fiber optic cables, and waves that travel through space without wires or cables, such as acoustic waves and electromagnetic waves, including radio, optical and infrared waves. The term computer-readable storage medium is used herein to refer to any medium that participates in providing information to processor 802, except for transmission media.

Common forms of computer-readable media include, for example, a floppy disk, a flexible disk, a hard disk, a magnetic tape, or any other magnetic medium, a compact disk ROM (CD-ROM), a digital video disk (DVD) or any other optical medium, punch cards, paper tape, or any other physical medium with patterns of holes, a RAM, a programmable ROM (PROM), an erasable PROM (EPROM), a FLASH-EPROM, or any other memory chip or cartridge, a carrier wave, or any other medium from which a computer can read. The term non-transitory computer-readable storage medium is used herein to refer to any medium that participates in providing information to processor 802, except for carrier waves and other signals.

Logic encoded in one or more tangible media includes one or both of processor instructions on a computer-readable storage media and special purpose hardware, such as ASIC 820.

Network link 878 typically provides information communication through one or more networks to other devices that use or process the information. For example, network link 878 may provide a connection through local network 880 to a host computer 882 or to equipment 884 operated by an Internet Service Provider (ISP). ISP equipment 884 in turn provides data communication services through the public, world-wide packet-switching communication network of networks now commonly referred to as the Internet 890. A computer called a server 892 connected to the Internet provides a service in response to information received over the Internet. For example, server 892 provides information representing video data for presentation at display 814.

The invention is related to the use of computer system 800 for implementing the techniques described herein. According to one embodiment of the invention, those techniques are performed by computer system 800 in response to processor 802 executing one or more sequences of one or more instructions contained in memory 804. Such instructions, also called software and program code, may be read into memory 804 from another computer-readable medium such as storage device 808. Execution of the sequences of instructions contained in memory 804 causes processor 802 to perform the method steps described herein. In alternative embodiments, hardware, such as application specific integrated circuit 820, may be used in place of or in combination with software to implement the invention. Thus, embodiments of the invention are not limited to any specific combination of hardware and software.

The signals transmitted over network link 878 and other networks through communications interface 870, carry information to and from computer system 800. Computer system 800 can send and receive information, including program code, through the networks 880, 890 among others, through network link 878 and communications interface 870. In an example using the Internet 890, a server 892 transmits program code for a particular application, requested by a message sent from computer 800, through Internet 890, ISP equipment 884, local network 880 and communications interface 870. The received code may be executed by processor 802 as it is received, or may be stored in storage device 808 or other non-volatile storage for later execution, or both. In this manner, computer system 800 may obtain application program code in the form of a signal on a carrier wave.

Various forms of computer readable media may be involved in carrying one or more sequence of instructions or data or both to processor 802 for execution. For example, instructions and data may initially be carried on a magnetic disk of a remote computer such as host 882. The remote computer loads the instructions and data into its dynamic memory and sends the instructions and data over a telephone line using a modem. A modem local to the computer system 800 receives the instructions and data on a telephone line and uses an infra-red transmitter to convert the instructions and data to a signal on an infra-red a carrier wave serving as the network link 878. An infrared detector serving as communications interface 870 receives the instructions and data carried in the infrared signal and places information representing the instructions and data onto bus 810. Bus 810 carries the information to memory 804 from which processor 802 retrieves and executes the instructions using some of the data sent with the instructions. The instructions and data received in memory 804 may optionally be stored on storage device 808, either before or after execution by the processor 802.

### 4. ALTERNATIVES, DEVIATIONS AND MODIFICATIONS

In the foregoing specification, the invention has been described with reference to specific embodiments thereof. It will, however, be evident that various modifications and changes may be made thereto without departing from the broader spirit and scope of the invention. The specification and drawings are, accordingly, to be regarded in an illustrative rather than a restrictive sense. Throughout this specification and the claims, unless the context requires otherwise, the word “comprise” and its variations, such as “comprises” and “comprising,” will be understood to imply the inclusion of a stated item, element or step or group of items, elements or steps but not the exclusion of any other item, element or step or group of items, elements or steps. Furthermore, the indefinite article “a” or “an” is meant to indicate one or more of the item, element or step modified by the article.

Notwithstanding that the numerical ranges and parameters setting forth the broad scope are approximations, the numerical values set forth in specific non-limiting examples are reported as precisely as possible. Any numerical value, however, inherently contains certain errors necessarily resulting from the standard deviation found in their respective testing measurements at the time of this writing. Furthermore, unless otherwise clear from the context, a numerical value presented herein has an implied precision given by the least significant digit. Thus, a value 1.1 implies a value from 1.05 to 1.15. The term “about” is used to indicate a broader range centered on the given value, and unless otherwise clear from the context implies a broader range around the least significant digit, such as “about 1.1” implies a range from 1.0 to 1.2. If the least significant digit is unclear, then the term “about” implies a factor of two, e.g., “about X” implies a value in the range from 0.5× to 2×, for example, about 100 implies a value in a range from 50 to 200. Moreover, all ranges disclosed herein are to be understood to encompass any and all sub-ranges subsumed therein. For example, a range of “less than 10” for a positive only parameter can include any and all sub-ranges between (and including) the minimum value of zero and the maximum value of 10, that is, any and all sub-ranges having a minimum value of equal to or greater than zero and a maximum value of equal to or less than 10, e.g., 1 to 4.

### 5. REFERENCES

Each of the following references is hereby incorporated by reference as if fully set forth herein, except for terminology inconsistent with that used herein.
Abdel-Rahman, Mohamed, et al. “Vanadium sesquioxide (V2O3)-based semiconducting temperature sensitive resistors for uncooled microbolometers.” Modern Physics Letters B 31.13 (2017): 1750145.
Chen, J., et al. “The I-V characteristics of double-barrier resonant tunneling diodes: Observation and calculation on their temperature dependence and asymmetry.” Journal of applied physics 70.6 (1991): 3131-3136.
Ko, Changhyun, and Shriram Ramanathan. “Stability of electrical switching properties in vanadium dioxide thin films under multiple thermal cycles across the phase transition boundary.” Journal of applied physics (2008): 086105.
Pfenning, Andreas, et al. “Nanothermometer based on resonant tunneling diodes: from cryogenic to room temperatures.” ACS nano 9.6 (2015): 6271-6277.
Reihani, Amin, Edgar Meyhofer, and Pramod Reddy. “Nanokelvin-resolution thermometry with a photonic microscale sensor at room temperature.” Nature Photonics 16.6 (2022): 422-427.
Sadat, Seid, E. Meyhofer, and Pramod Reddy. “High resolution resistive thermometry for micro/nanoscale measurements.” Review of Scientific Instruments 83.8 (2012): 084902.adat, Seid, et al. “Room temperature picowatt-resolution calorimetry.” Applied Physics Letters 99.4 (2011): 043106.
Weng, Wenle, et al. “Nano-Kelvin thermometry and temperature control: beyond the thermal noise limit.” Physical review letters 112.16 (2014): 160801.

What is claimed is:

1. An apparatus for ultra-high resolution thermometry, said apparatus comprising:
a semiconductor tunneling diode configured to be placed in thermal contact with a sample;
an electrical resistor electrically connected in series with and up current of the semiconductor tunneling diode to define a discontinuous edge between a tunneling current and a diffusion current of the semiconductor tunneling diode, with the discontinuous edge having a peak current and a valley current;
a voltage source electrically connected in series with and up current of the electrical resistor and configured to produce a constant voltage V_{DC} summed with a time oscillating voltage V_{AC}, with the time oscillating voltage V_{AC} causing an operating point of the semiconductor tunneling diode to oscillate between the peak current and the valley current; and
a processor configured to determine temperature at the semiconductor tunneling diode based at least in part on a current signal output from the semiconductor tunneling diode.

2. The apparatus as recited in claim 1, further comprising a low pass filter or lock-in amplifier connected in series with and down current of the semiconductor tunneling diode and in series and up current of the processor.

3. The apparatus as recited in claim 1, wherein the processor is further configured to determine temperature at the semiconductor tunneling diode based on the current signal output from the semiconductor tunneling diode and a calibration function that relates the current signal output to temperature based on calibration data for samples with known temperatures.

4. The apparatus as recited in claim 1, further comprising a transimpedance amplifier configured to convert a current signal output from the semiconductor tunneling diode to a voltage signal.

5. The apparatus as recited in claim 1, further comprising an analog to digital converter configured to convert an analog signal down current from the semiconductor tunneling diode to a digital data sequence input to the processor.

6. The apparatus as recited in claim 1, wherein the voltage source further comprises:
a precision voltage reference configured to output a constant voltage;
a waveform generator configured to output a temporally oscillating voltage; and
a summing amplifier configured to combine with variable gains the constant voltage and the temporally oscillating voltage to produce the constant voltage V_{DC} summed with the time oscillating voltage V_{AC}.

7. The apparatus as recited in claim 1, wherein the processor is configured to determine temperature at the semiconductor tunneling diode based on a duty cycle width of the current signal output from the semiconductor tunneling diode or of a voltage signal based on the current signal.

8. The apparatus as recited in claim 1, wherein the processor is configured to determine temperature at the semiconductor tunneling diode based on a time average of the current signal output from the semiconductor tunneling diode or of a voltage signal based on the current signal.

9. The apparatus as recited in claim 1, wherein the processor is further configured to determine heat flow in a sample in thermal contact with the semiconductor tunneling diode.

10. The apparatus as recited in claim 1, further comprising a thermal conductor configured to provide thermal contact between the semiconductor tunneling diode and a sample.

11. A system comprising:
the apparatus of claim 1; and
a container configured to hold a sample in thermal contact with the semiconductor tunneling diode.

12. A bolometer comprising:
a semiconductor tunneling diode configured to be exposed to electromagnetic radiation;
an electrical resistor electrically connected in series with and up current of the semiconductor tunneling diode to define a discontinuous edge between a tunneling current and a diffusion current of the semiconductor tunneling diode, with the discontinuous edge having a peak current and a valley current;
a voltage source electrically connected in series with and up current of the electrical resistor and configured to produce a constant voltage V_{DC} summed with a time oscillating voltage V_{AC}, with the time oscillating voltage V_{AC} causing an operating point of the semiconductor tunneling diode to oscillate between the peak current and the valley current; and
a processor configured to determine temperature at the semiconductor tunneling diode based at least in part on a current signal output from the semiconductor tunneling diode.

13. The bolometer as recited in claim 12, wherein the semiconductor tunneling diode is configured as a heavily-doped semiconductor tunneling diode having a free carrier density of at least 10¹⁸ cm⁻³ and greater, with the heavily-doped semiconductor tunneling diode enhancing detection of the electromagnetic radiation.

14. The bolometer as recited in claim 13, wherein the heavily-doped semiconductor tunneling diode absorbs photons in the electromagnetic radiation and emits phonons in response to the absorbed photons, with the phonons assisting in tunneling of particles through a positive-to-negative (P-N) junction of the heavily-doped semiconductor tunneling diode.

15. The bolometer as recited in claim 12, further comprising: an absorber layer on an upper surface of the semiconductor tunneling diode and exposed to the electromagnetic radiation, with the absorber layer configured to enhance detection of the electromagnetic radiation.

16. The bolometer as recited in claim 15, wherein the absorber layer absorbs photons in the electromagnetic radiation and emits phonons in response to the absorbed photons, with the phonons assisting in tunneling of particles through a positive-to-negative (P-N) junction of the semiconductor tunneling diode.

17. The bolometer as recited in claim 15, wherein the absorber layer comprises one of silicon nitride (SiNₓ), silicon dioxide (SiO₂), barium titanate (BaTiO₃), or any polar dielectric.

18. The bolometer as recited in claim 12, wherein a broadband wavelength of the electromagnetic radiation being detected is in a range of 2 to 40 microns.

19. The bolometer as recited in claim 12, further comprising a low pass filter or a lock-in amplifier connected in series with and down current of the semiconductor tunneling diode and in series and up current of the processor.

20. The bolometer as recited in claim 12, wherein the processor is further configured to determine temperature at the semiconductor tunneling diode based on the current signal output from the semiconductor tunneling diode and a calibration function that relates the current signal output to temperature based on calibration data for samples with known temperatures.

21. The bolometer as recited in claim 12, further comprising a transimpedance amplifier configured to convert a current signal output from the semiconductor tunneling diode to a voltage signal.

22. The bolometer as recited in claim 12, further comprising an analog to digital converter configured to convert an analog signal down current from the semiconductor tunneling diode to a digital data sequence input to the processor.

23. The bolometer as recited in claim 12, wherein the voltage source further comprises:
a precision voltage reference configured to output a constant voltage;
a waveform generator configured to output a temporally oscillating voltage; and
a summing amplifier configured to combine with variable gains the constant voltage and the temporally oscillating voltage to produce the constant voltage V_{DC} summed with the time oscillating voltage V_{AC}.

24. The bolometer as recited in claim 12, wherein the processor is configured to determine temperature at the semiconductor tunneling diode based on a duty cycle width of the current signal output from the semiconductor tunneling diode or of a voltage signal based on the current signal, or based on the time-averaged amplitude of the current signal, or based on the amplitude of the oscillation of the current signal.

25. A microfluidic calorimeter comprising:
at least one temperature-controlled thermal shield,
a microfluidic channel in thermal contact with the at least one temperature-controlled thermal shield, and comprising a fluid or gas and a sample within the microfluidic channel,
a first semiconductor tunneling diode coupled to the microfluidic channel and adjacent the sample,
a first electrical resistor electrically connected in series with and up current of the first semiconductor tunneling diode to define a discontinuous edge between a tunneling current and a diffusion current of the first semiconductor tunneling diode, with the discontinuous edge having a peak current and a valley current,
a second semiconductor tunneling diode coupled to the microfluidic channel and spaced away from the sample,
a second electrical resistor electrically connected in series with and up current of the second semiconductor tunneling diode to define a discontinuous edge between a tunneling current and a diffusion current of the second semiconductor tunneling diode, with the discontinuous edge having a peak current and a valley current, a voltage source electrically connected in series with and up current of the first and second electrical resistors and configured to produce a constant voltage V_{DC} summed with a time oscillating voltage V_{AC}, with the time oscillating voltage V_{AC} causing an operating point of the first and second semiconductor tunneling diodes to respectively oscillate between the peak current and the valley current, and
a processor configured to determine respective temperatures at the first and second semiconductor tunneling diodes based at least in part on a respective current signal output from the first and second semiconductor tunneling diodes, with the respective temperatures being used by the processor to determine a heat flow released by the sample.

26. The microfluidic calorimeter as recited in claim 25, wherein the at least one temperature-controlled thermal shield provides a vacuum environment for the microfluidic channel in thermal.

27. The microfluidic calorimeter as recited in claim 25, wherein the sample comprises at least one of biological, single cell, solution, nanomaterial and powder.

28. The microfluidic calorimeter as recited in claim 25, is configured as an isothermal microfluidic calorimeter.

29. The microfluidic calorimeter as recited in claim 25, further comprising:
a reference microfluidic channel in thermal contact with the at least one temperature-controlled thermal shield, and comprising a fluid or gas within the reference microfluidic channel,
a third semiconductor tunneling diode coupled to the reference microfluidic channel,
a third electrical resistor electrically connected in series with and up current of the third semiconductor tunneling diode to define a discontinuous edge between a tunneling current and a diffusion current of the third semiconductor tunneling diode, with the discontinuous edge having a peak current and a valley current,
a fourth semiconductor tunneling diode coupled to the microfluidic channel and spaced away from the third semiconductor tunneling diode, and
a fourth electrical resistor electrically connected in series with and up current of the fourth semiconductor tunneling diode to define a discontinuous edge between a tunneling current and a diffusion current of the fourth semiconductor tunneling diode, with the discontinuous edge having a peak current and a valley current,
wherein the voltage source is electrically connected in series with and up current of the third and fourth electrical resistors and configured to produce a constant voltage V_{DC} summed with a time oscillating voltage V_{AC}, with the time oscillating voltage V_{AC} causing an operating point of the third and fourth semiconductor tunneling diodes to respectively oscillate between the peak current and the valley current, and
wherein the processor is further configured to determine respective temperatures at the third and fourth semiconductor tunneling diodes based at least in part on a respective current signal output from the third and fourth semiconductor tunneling diodes, with the respective temperatures being used by the processor to determine a heat flow released by the sample.

30. The microfluidic calorimeter as recited in claim 29, is configured as a differential isothermal microfluidic calorimeter.

31. The microfluidic calorimeter as recited in claim 25, further comprising at least one low pass filter or lock-in amplifier connected in series with and down current of the first and second semiconductor tunneling diodes and in series and up current of the processor.

32. The microfluidic calorimeter as recited in claim 25, wherein the processor is further configured to determine temperature at the first semiconductor tunneling diode based on the current signal output from the first and second semiconductor tunneling diodes and a calibration function that relates the current signal output to temperature based on calibration data for samples with known temperatures.

33. The microfluidic calorimeter as recited in claim 25, further comprising at least one transimpedance amplifier configured to convert a current signal output from the first and second semiconductor tunneling diodes to a voltage signal.

34. The microfluidic calorimeter as recited in claim 25, further comprising at least one analog to digital converter configured to convert an analog signal down current from the respective first and second semiconductor tunneling diodes to a digital data sequence input to the processor.

35. The microfluidic calorimeter as recited in claim 25, wherein the voltage source further comprises:
a precision voltage reference configured to output a constant voltage;
a waveform generator configured to output a temporally oscillating voltage; and
a summing amplifier configured to combine with variable gains the constant voltage and the temporally oscillating voltage to produce the constant voltage V_{DC} summed with the time oscillating voltage V_{AC}.

36. The microfluidic calorimeter as recited in claim 25, wherein the processor is configured to determine temperature at the first and second semiconductor tunneling diodes based on a duty cycle width of the current signal output from the first and second semiconductor tunneling diodes or of a voltage signal based on the current signal.

37. The microfluidic calorimeter as recited in claim 25, wherein the processor is configured to determine temperature at the first and second semiconductor tunneling diodes based on a time average of the current signal output from the first and second semiconductor tunneling diodes or of a voltage signal based on the current signal.
